(19) United States
(12) Patent Application Publication
(10) Pub. No.: US 2024/0347486 A1
(43) Pub. Date: Oct. 17, 2024

(54) INTEGRATED CIRCUIT FLIP-CHIP AND LIGHT-EMITTING DEVICE

(71) Applicant: LITE-ON TECHNOLOGY CORPORATION, TAIPEI CITY (TW)

(72) Inventors: CHEN-HSIU LIN, NEW TAIPEI CITY (TW); MIN-HSI CHEN, Taipei City (TW); CHANG-HUNG HSIEH, New Taipei City (TW); SHAN-HUI CHEN, Taoyuan City (TW); YU-HSUAN CHU, Taipei City (TW)

(21) Appl. No.: 18/677,837

(22) Filed: May 29, 2024

Related U.S. Application Data
(63) Continuation-in-part of application No. 17/391,014, filed on Aug. 1, 2021, now Pat. No. 12,009,459.
(60) Provisional application No. 63/065,547, filed on Aug. 14, 2020.

(30) Foreign Application Priority Data
May 6, 2021 (CN) 202110492505.4
May 13, 2024 (CN) 202421028044.0

(51) Int. Cl. H01L 23/00; H01L 23/31; H01L 23/538; H01L 25/16

(52) U.S. Cl. CPC H01L 24/04; H01L 23/5383; H01L 25/167; H01L 23/3107; H01L 24/32; H01L 2224/02375; H01L 2224/04026; H01L 2224/32225

(57) ABSTRACT

An integrated circuit (IC) flip-chip and a light-emitting device are provided. The IC flip-chip includes a chip body, a plurality of metal pads, and a plurality of flip-chip pads. The chip body has a surface. The metal pads are disposed on the surface of the chip body. The flip-chip pads are disposed on the metal pads, and the flip-chip pads are electrically coupled to the metal pads through a redistribution layer therebetween. A distribution of the flip-chip pads is more even than a distribution of the metal pads.

### CROSS-REFERENCE TO RELATED PATENT APPLICATION

This application is a Continuation-In-Part of the U.S. application Ser. No. 17/391,014, filed on Aug. 1, 2021 and entitled “LIGHT-EMITTING DEVICE, LIGHT-EMITTING ASSEMBLY, AND INTEGRATED CIRCUIT FLIP-CHIP”, now pending.

Moreover, this application claims the benefit of priority to China Patent Application No. 202421028044.0, filed on May 13, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip, and more particularly to an integrated circuit flip-chip and a light-emitting device.

### BACKGROUND OF THE DISCLOSURE

Conventional integrated circuit (IC) chips for driving light-emitting diode (LED) flip-chips are equipped with a plurality of wire bonding pads that are only suitable for being used in wire bonding processes. However, the structure of any light-emitting device having the conventional IC chips will be affected by the arrangement of the wire bonding pads, thereby hindering further architectural improvements to the light-emitting device having the conventional IC chips.

### SUMMARY OF THE DISCLOSURE

In response to the above-referenced technical inadequacies, the present disclosure provides an integrated circuit flip-chip and a light-emitting device.

In order to solve the above-mentioned problems, one of the technical aspects adopted by the present disclosure is to provide an integrated circuit (IC) flip-chip. The IC flip-chip includes a chip body, a plurality of metal pads, and a plurality of flip-chip pads. The chip body has a surface. The metal pads are disposed on the surface of the chip body. The flip-chip pads are disposed on the metal pads. The flip-chip pads are electrically coupled to the metal pads through a redistribution layer therebetween. A distribution of the flip-chip pads is more even than a distribution of the metal pads.

In one of the possible or preferred embodiments, any one of the metal pads is not covered by a projection area formed by an orthographic projection of the flip-chip pads on the surface of the chip body.

In one of the possible or preferred embodiments, edges of the metal pads define a layout boundary, and the flip-chip pads are arranged within the layout boundary.

In one of the possible or preferred embodiments, the layout boundary defines a nine-square grid area, a number of spaces of the nine-square grid area on which the flip-chip pads are located is greater than a number of spaces of the nine-square grid area on which the metal pads are located.

In one of the possible or preferred embodiments, edges of part of the flip-chip pads are partially located on the layout boundary, and a remaining part of the flip-chip pads is spaced apart from the layout boundary.

In one of the possible or preferred embodiments, the redistribution layer includes a first polymer layer, a wire extension layer, and a second polymer layer. The first polymer layer is formed on the surface of the chip body and arranged around the metal pads. The wire extension layer is disposed on the first polymer layer and the metal pads. The wire extension layer is electrically coupled to the metal pads. The second polymer layer is arranged around the wire extension layer. A portion of the wire extension layer is located on an outer side of the second polymer layer.

In one of the possible or preferred embodiments, the redistribution layer further includes a solder mask layer that is disposed on the second polymer layer and the wire extension layer, and the flip-chip pads are exposed from the solder mask layer.

In one of the possible or preferred embodiments, any one of the flip-chip pads is not located in a central region of the layout boundary.

In one of the possible or preferred embodiments, each side edge of the layout boundary corresponds in position to at least two of the flip-chip pads.

In one of the possible or preferred embodiments, the flip-chip pads are symmetrically arranged along at least one axis passing through a center point of the layout boundary.

In one of the possible or preferred embodiments, at least one of the flip-chip pads is configured to move toward an inner side of the layout boundary.

In one of the possible or preferred embodiments, a material of any one of the flip-chip pads is different from a material of any one of the metal pads.

In one of the possible or preferred embodiments, each of the flip-chip pads has a same area.

In one of the possible or preferred embodiments, an area of any one of the flip-chip pads is larger than an area of the metal pad that is electrically coupled thereto.

In order to solve the above-mentioned problems, another one of the technical aspects adopted by the present disclosure is to provide a light-emitting device. The light-emitting device includes a substrate, the above-mentioned IC flip-chip, and at least one light-emitting diode (LED) flip-chip. The IC flip-chip is disposed on the substrate. The at least one LED flip-chip is spaced apart from the IC flip-chip. The at least one LED flip-chip is electrically coupled to the IC flip-chip by the substrate.

In one of the possible or preferred embodiments, the substrate includes a first layer board, a second layer board, a third layer board, and a fourth layer board. The IC flip-chip and the at least one LED flip-chip are disposed on the first layer board. The second layer board is disposed on one side of the first layer board. The second layer board includes an upper insulating layer, a plurality of first conductive pads, and a plurality of first conductive pillars. The first conductive pads are disposed on the upper insulating layer, and the first conductive pads are electrically coupled to the flip-chip pads through the first conductive pillars. The third layer board is disposed on a side of the second layer board away from the first layer board. The third layer board includes a lower insulating layer, a plurality of second conductive pads, and a plurality of second conductive pillars. The second conductive pads are disposed on the lower insulating layer, and the second conductive pads are electrically coupled to the first conductive pads through the second conductive pillars. The fourth layer board is disposed on a side of the third layer board away from the first layer board. The fourth layer board includes a plurality of outer pads, and the outer pads are electrically coupled to the second conductive pads.

In one of the possible or preferred embodiments, a first predetermined separation distance is between any two adjacent ones of the first conductive pads and between any two adjacent ones of the second conductive pads, and a second predetermined separation distance is between one of the first conductive pads adjacent to an edge of the upper insulating layer and the edge of the upper insulating layer, and between one of the second conductive pads adjacent to an edge of the lower insulating layer and the edge of the lower insulating layer. Each of the first predetermined separation distance and the second predetermined separation distance is 60 microns.

In one of the possible or preferred embodiments, the at least one LED flip-chip includes a red light diode chip, a green light diode chip, and a blue light diode chip. A long axis of the red light diode chip, a long axis of the green light diode chip, and a long axis of the blue light diode chip are parallel to each other, and the red light diode chip, the green light diode chip, and the blue light diode chip have a triangular arrangement.

In one of the possible or preferred embodiments, the at least one LED flip-chip includes a red light diode chip, a green light diode chip, a blue light diode chip, and a white light diode chip. A short axis extension line of the red light diode chip, a short axis extension line of the green light diode chip, and a short axis extension line of the blue light diode chip overlap with each other, and the white light diode chip is arranged on a common side of the red light diode chip, the green light diode chip and the blue light diode chip.

Therefore, in the integrated circuit flip-chip and the light-emitting device provided by the present disclosure, by virtue of “a distribution of the flip-chip pads being more even than a distribution of the metal pads,” the integrated circuit flip-chip and the light-emitting device can provide ideal product reliability while being miniaturized.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a perspective view of a light-emitting device according to a first embodiment of the present disclosure;

FIG. 2 is an exploded view of FIG. 1;

FIG. 3 is an exploded view of an integrated circuit (IC) flip-chip of

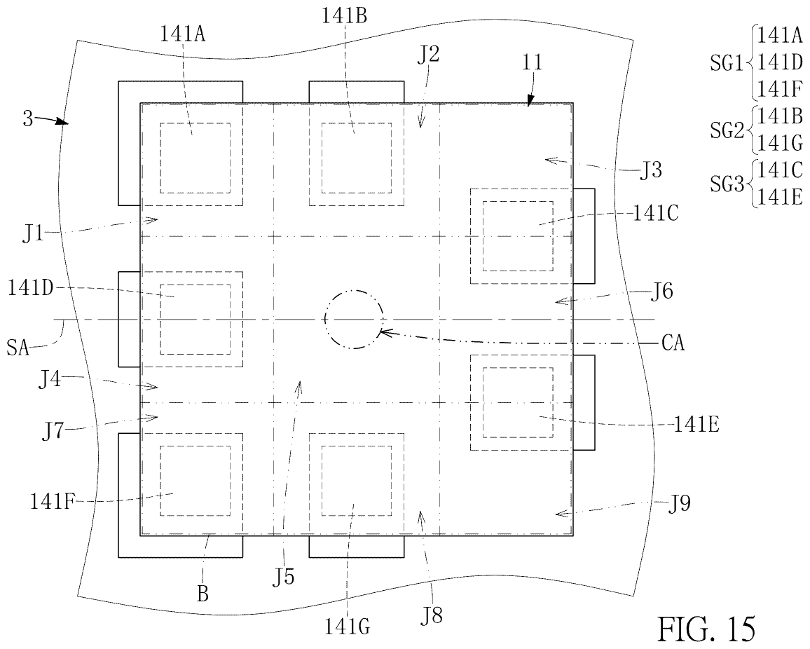

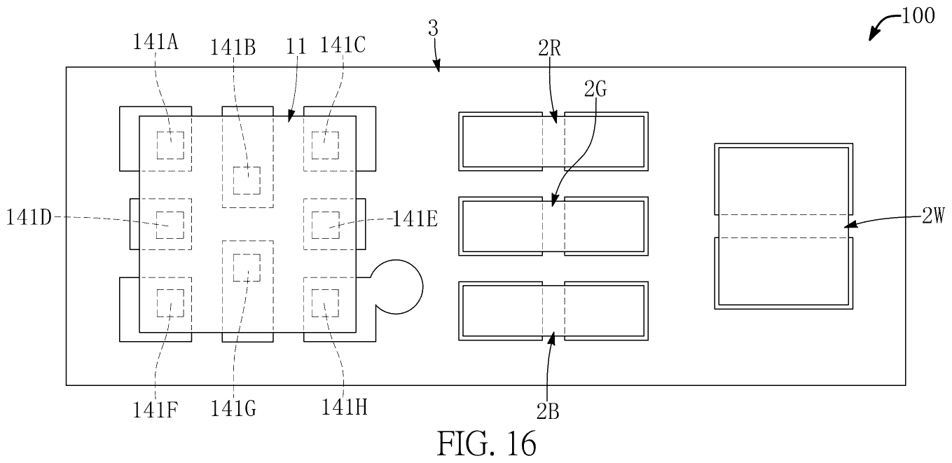

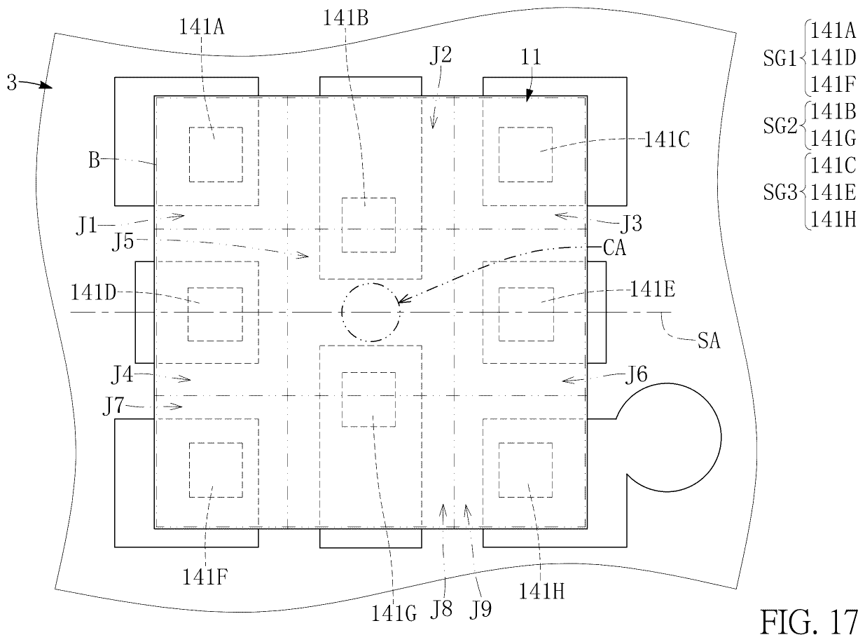

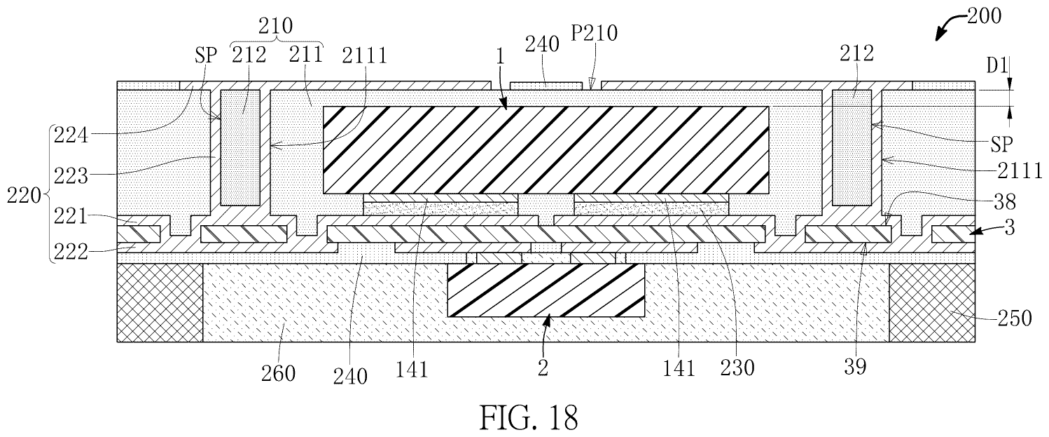

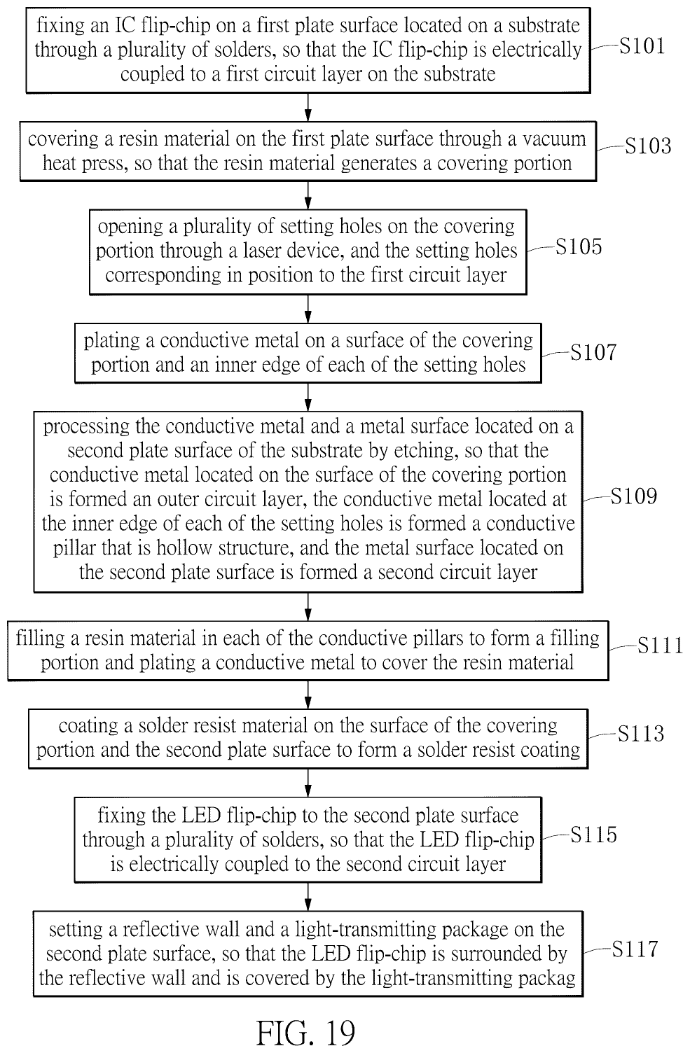

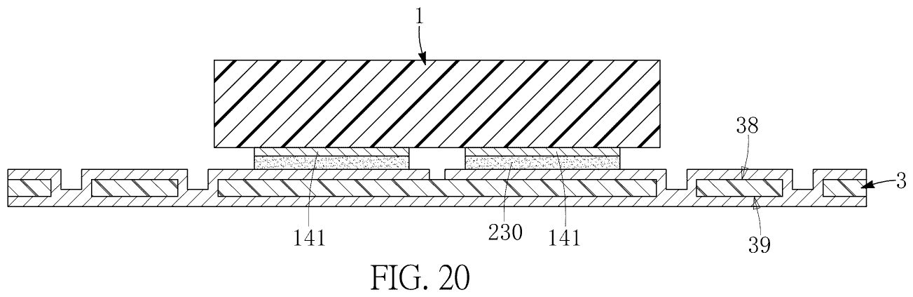

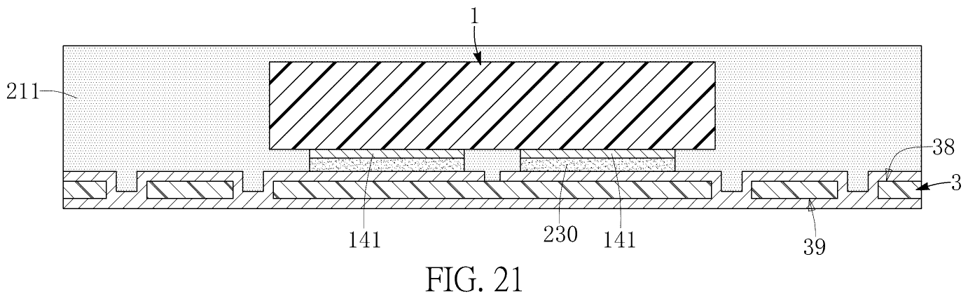

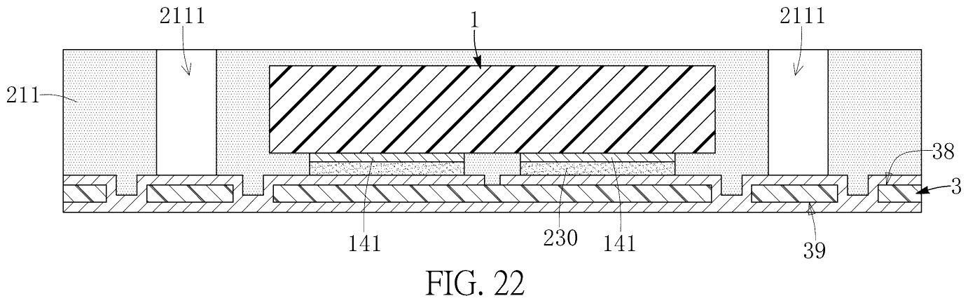

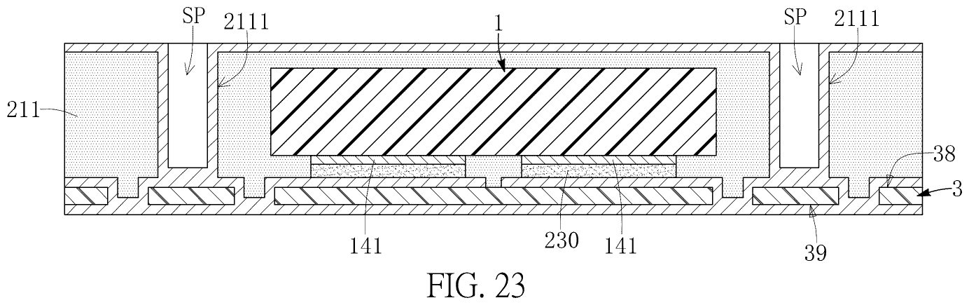

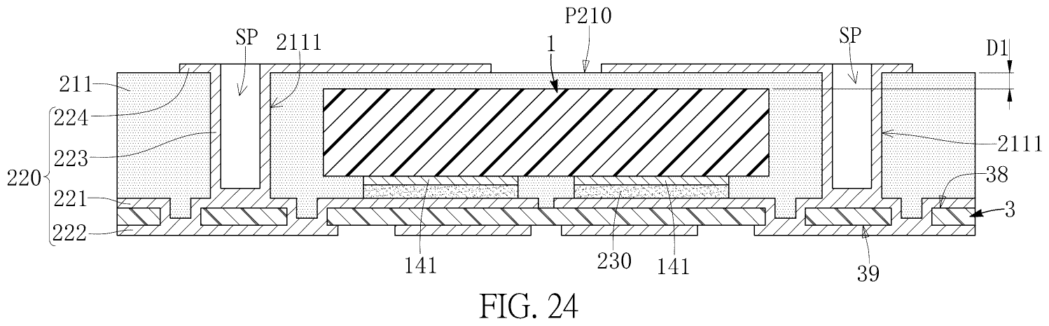

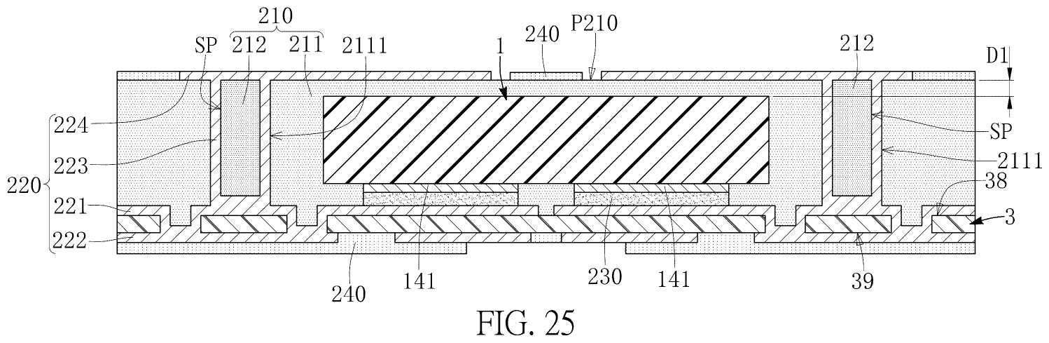

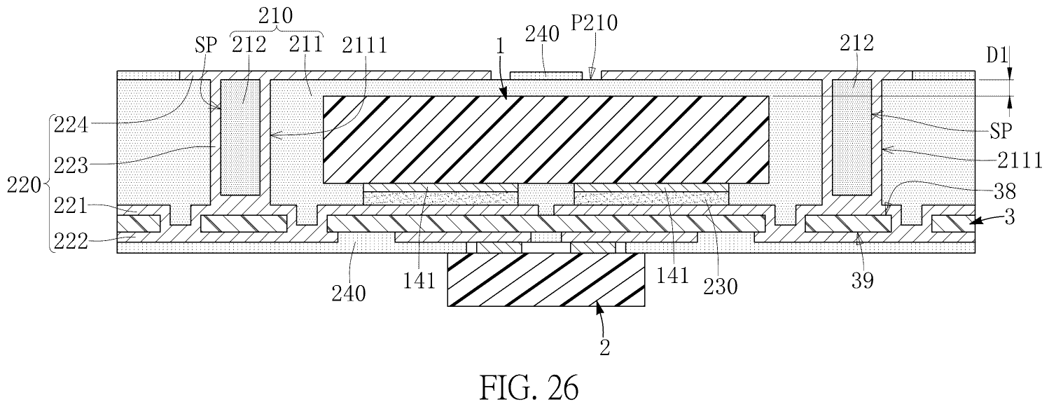

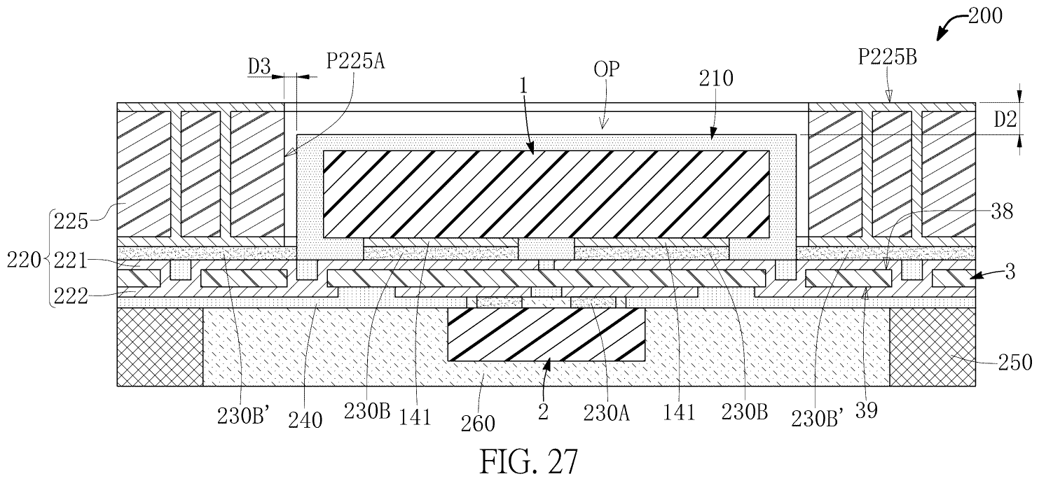

FIG. 2;

FIG. 4 is a cross-sectional view taken along line IV-IV of FIG. 2;

FIG. 5 is a bottom view of the IC flip-chip of FIG. 2 with a solder mask layer being omitted;

FIG. 6 is an exploded view of a substrate of FIG. 2;

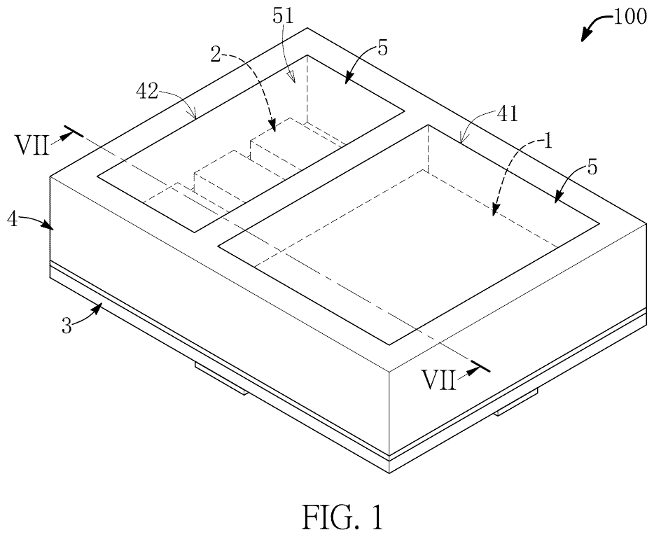

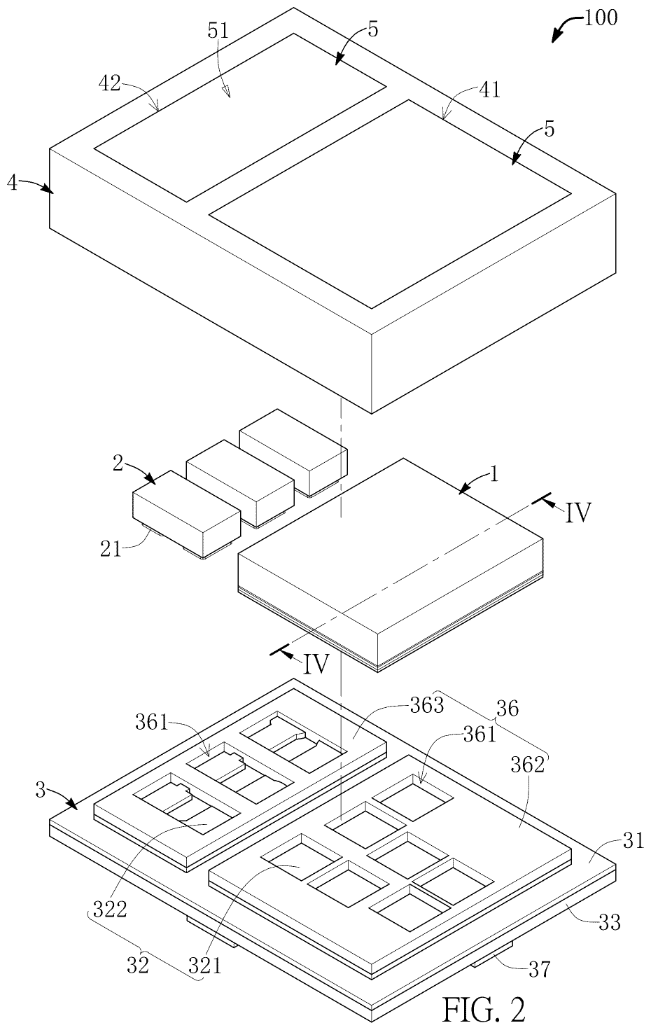

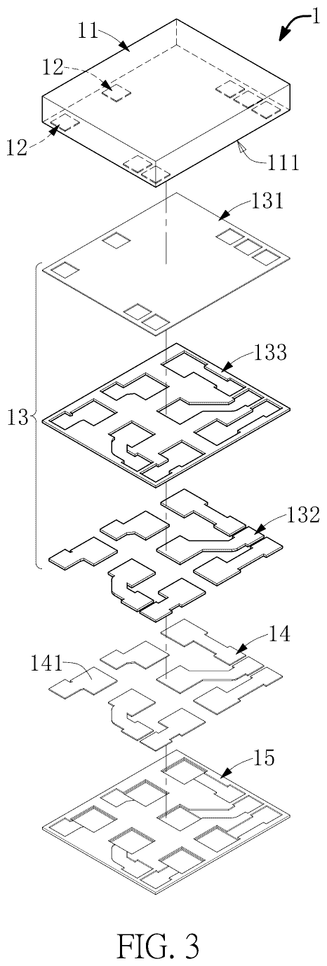

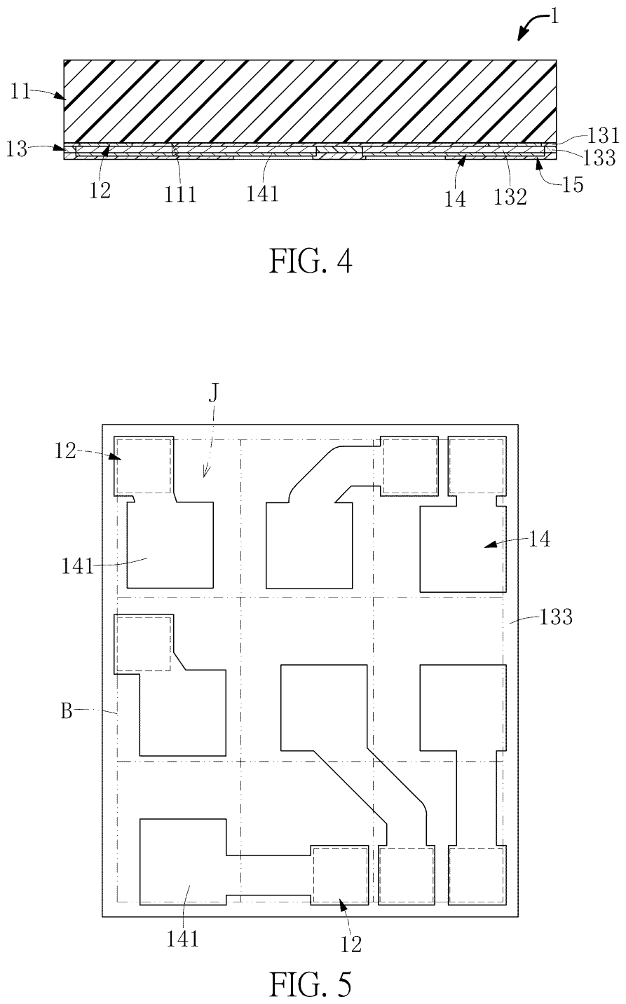

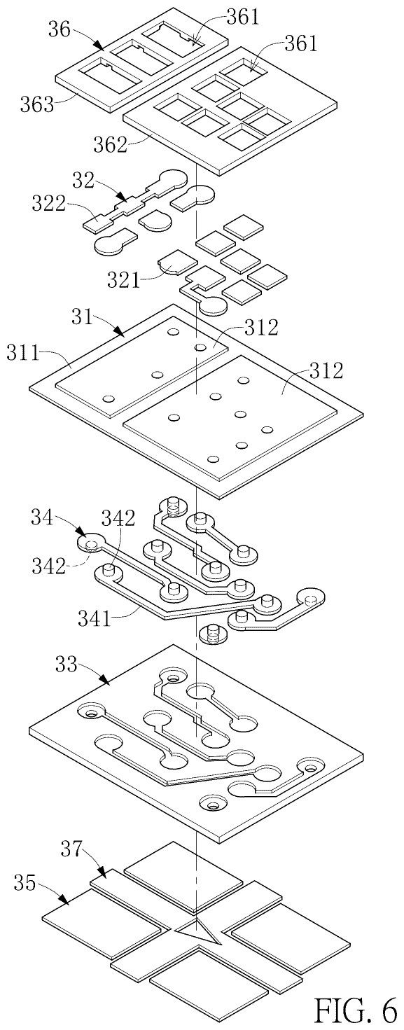

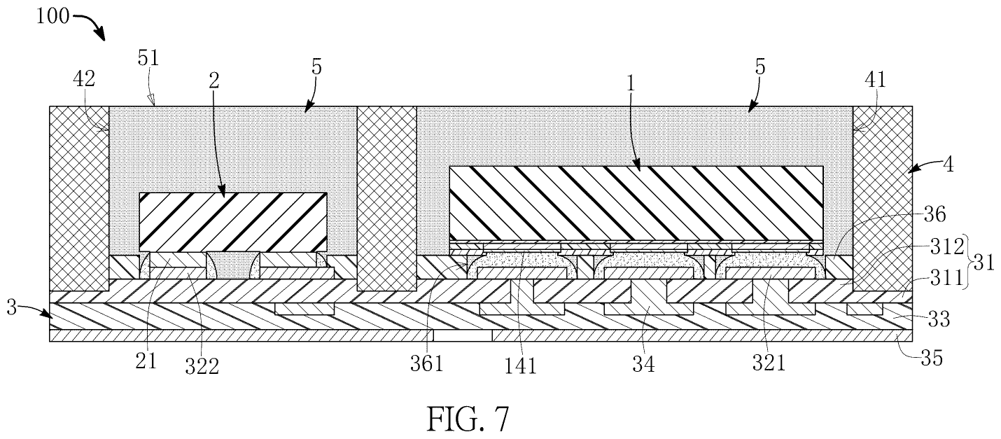

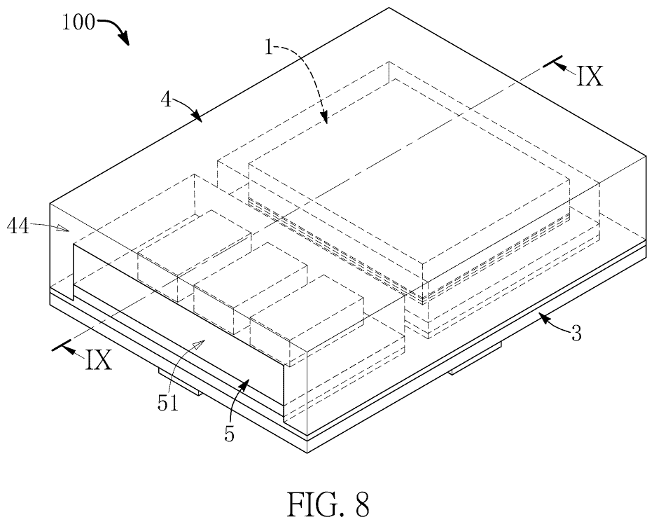

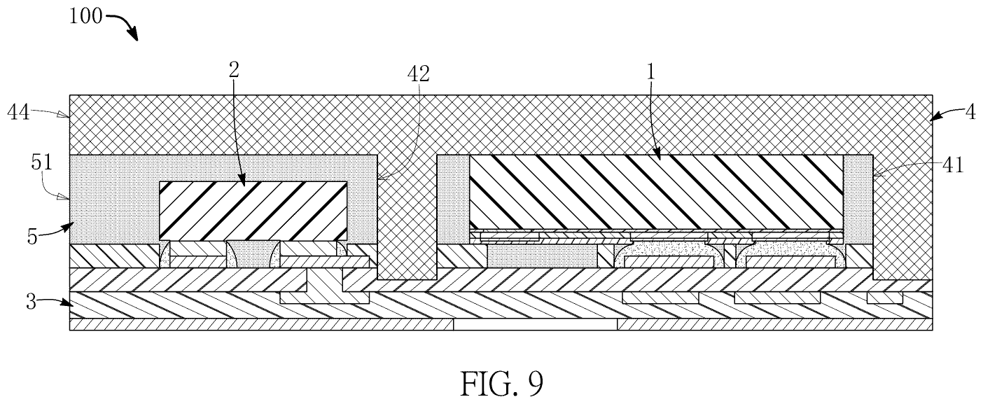

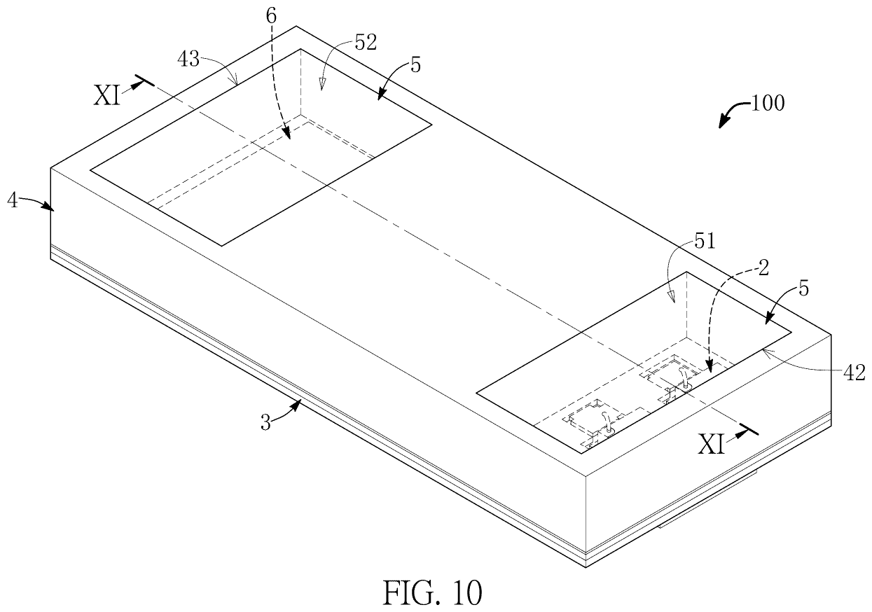

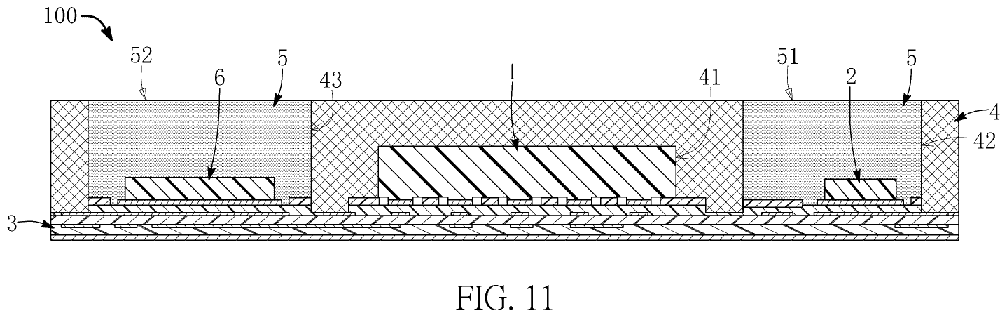

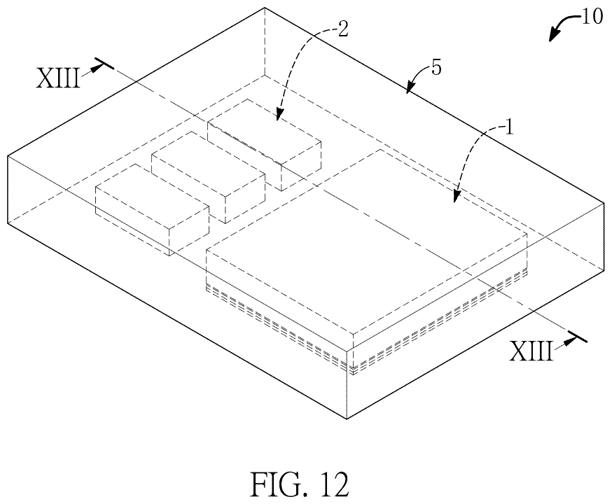

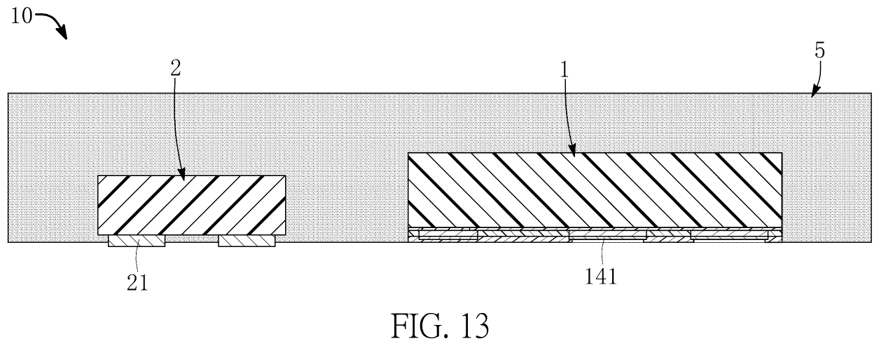

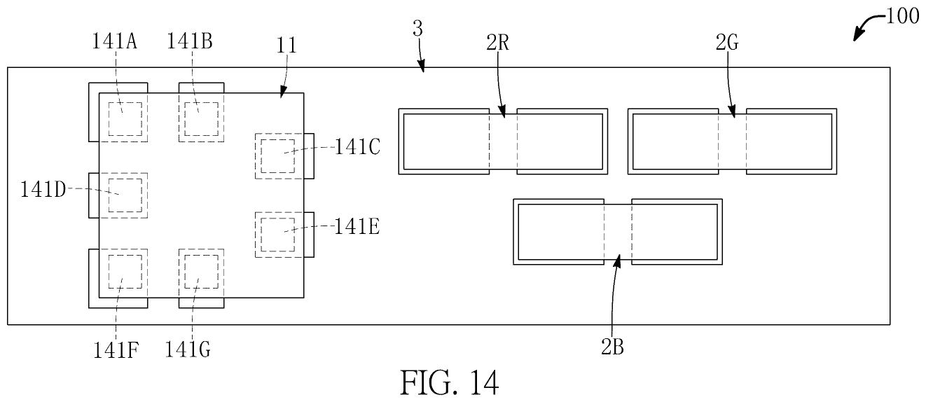

FIG. 7 is a cross-sectional view taken along line VII-VII of FIG. 1;

FIG. 8 is a perspective view of the light-emitting device according to a second embodiment of the present disclosure;

FIG. 9 is a cross-sectional view taken along line IX-IX of FIG. 8;

FIG. 10 is a perspective view of the light-emitting device according to a third embodiment of the present disclosure;

FIG. 11 is a cross-sectional view taken along line XI-XI of FIG. 10;

FIG. 12 is a perspective view of a light-emitting assembly according to a fourth embodiment of the present disclosure;

FIG. 13 is a cross-sectional view taken along line XIII-XIII of FIG. 12;

FIG. 14 is a top view of the light-emitting device (with a surrounding wall being omitted) according to a fifth embodiment of the present disclosure;

FIG. 15 is a schematic enlarged view of a portion of FIG. 14;

FIG. 16 is another top view of the light-emitting device (with the surrounding wall being omitted) according to the fifth embodiment of the present disclosure;

FIG. 17 is a schematic enlarged view of a portion of FIG. 16;

FIG. 18 is a cross-sectional view of the light-emitting device according to a sixth embodiment of the present disclosure;

FIG. 19 is a flowchart of a manufacturing method of the light-emitting device according to the sixth embodiment of the present disclosure;

FIG. 20 is a schematic view of step S101 of the manufacturing method in FIG. 19;

FIG. 21 is a schematic view of step S103 of the manufacturing method in FIG. 19;

FIG. 22 is a schematic view of step S105 of the manufacturing method in FIG. 19;

FIG. 23 is a schematic view of step S107 of the manufacturing method in FIG. 19;

FIG. 24 is a schematic view of step S109 of the manufacturing method in FIG. 19;

FIG. 25 is a schematic view of step S111 and step S113 of the manufacturing method in FIG. 19;

FIG. 26 is a schematic view of step S115 of the manufacturing method in FIG. 19;

FIG. 27 is a cross-sectional view of the light-emitting device according to a seventh embodiment of the present disclosure;

FIG. 28 is a flowchart of the manufacturing method of the light-emitting device according to the seventh embodiment of the present disclosure;

FIG. 29 is a schematic view of step S201 of the manufacturing method in FIG. 28;

FIG. 30 is a schematic view of step S203 of the manufacturing method in FIG. 28;

FIG. 31 is a schematic view of step S205 of the manufacturing method in FIG. 28;

FIG. 32 is a schematic view of step S207 of the manufacturing method in FIG. 28;

FIG. 33 is another flowchart of the manufacturing method of the light-emitting device according to the seventh embodiment of the present disclosure;

FIG. 34 is a schematic view of step S301 of the manufacturing method in FIG. 33;

FIG. 35 is a schematic view of step S303 of the manufacturing method in FIG. 33;

FIG. 36 is a schematic view of step S305 of the manufacturing method in FIG. 33;

FIG. 37 is a schematic view of step S307 of the manufacturing method in FIG. 33;

FIG. 38 is a schematic view of step S309 of the manufacturing method in FIG. 33; and

FIG. 39 is a schematic view of step S311 of the manufacturing method in FIG. 33.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

Referring to FIG. 1 to FIG. 7, a first embodiment of the present disclosure is shown. As shown in FIG. 1 and FIG. 2, a light-emitting device (or a light-emitting diode package structure) 100 is provided. The light-emitting device 100 includes an integrated circuit (IC) flip-chip 1, at least one light-emitting diode (LED) flip-chip 2, a substrate 3, a surrounding wall 4, and a light-permeable package body 5. The IC flip-chip 1 and the at least one LED flip-chip 2 are mounted on the substrate 3. For instance, a solder paste can be disposed on the substrate 3 through stencil apertures in a solder paste printing process. Accordingly, the IC flip-chip 1 and the at least one LED flip-chip 2 can be mounted on the substrate 3 through the solder paste.

The entire thickness of the light-emitting device 100 of the present disclosure can be reduced by replacing solder ball (or solder bump) with the solder paste. The surrounding wall 4 is formed on the substrate 3 and surrounds outer sides of the IC flip-chip 1 and the at least one LED flip-chip 2. The light-permeable package body 5 is disposed in the surrounding wall 4 and is formed on the substrate 3. Accordingly, the IC flip-chip 1 and the at least one LED flip-chip 2 are embedded in the light-permeable package body 5.

It should be noted that the IC flip-chip 1 in the present embodiment is described with the above-mentioned components. However, the present disclosure is not limited thereto. For instance, in other embodiments not shown in the present disclosure, the IC flip-chip 1 can be independently used (e.g., sold) or can be used in cooperation with other components. The following description will describe the construction and connection relationship of each component of the light-emitting device 100. In addition, for convenience of explanation, a quantity of the at least one LED flip-chip is described as multiple, but the quantity of the at least one LED flip-chip in the present disclosure can be adjusted to one according to practical requirements.

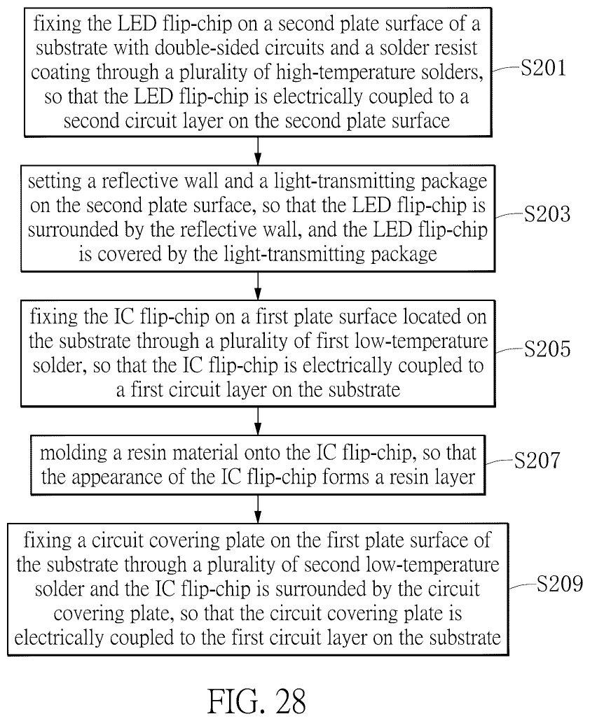

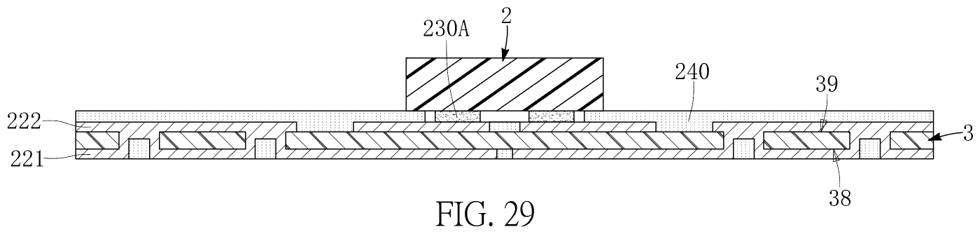

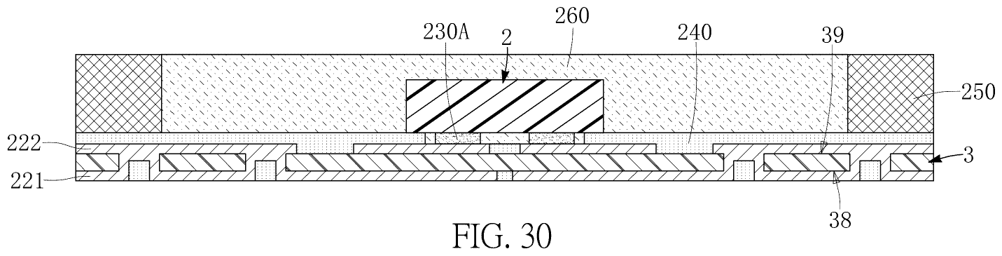

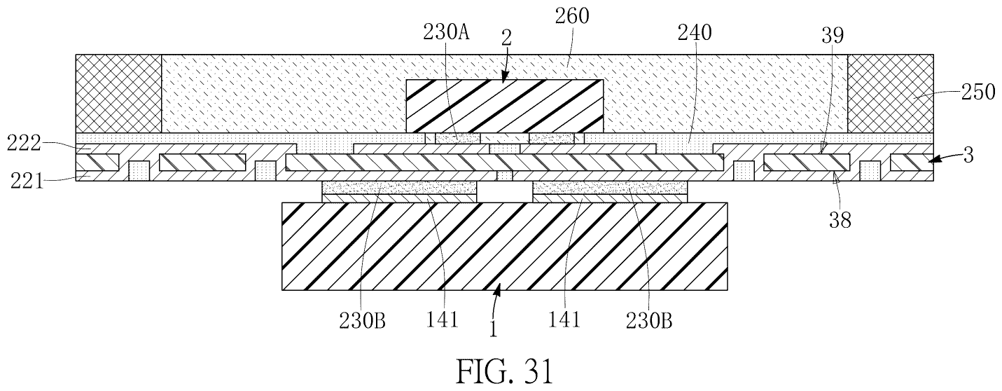

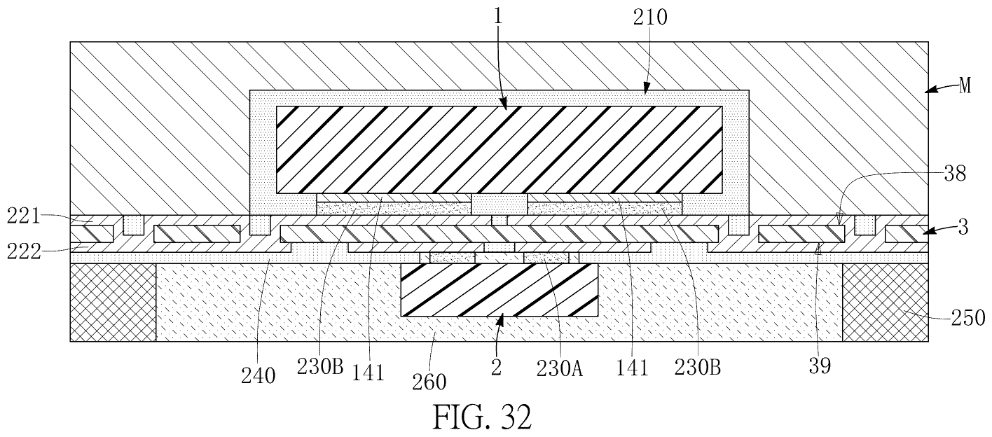

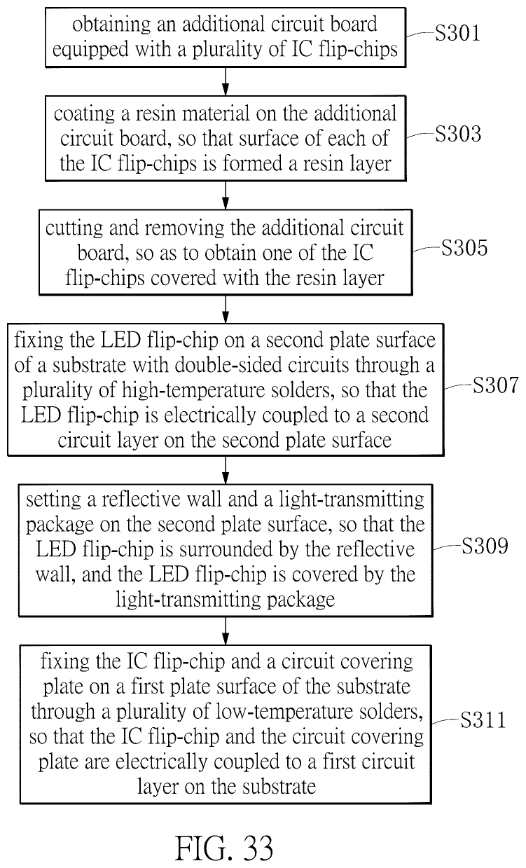

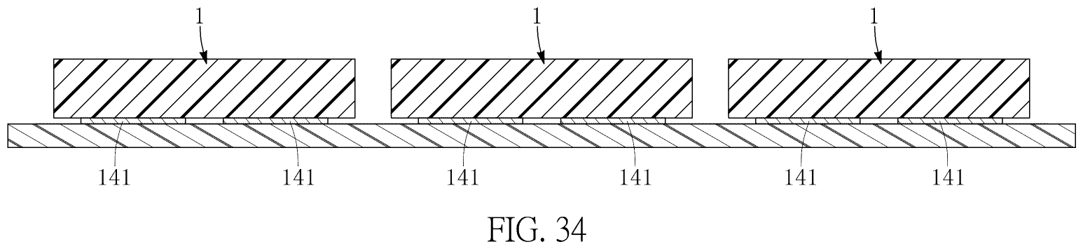

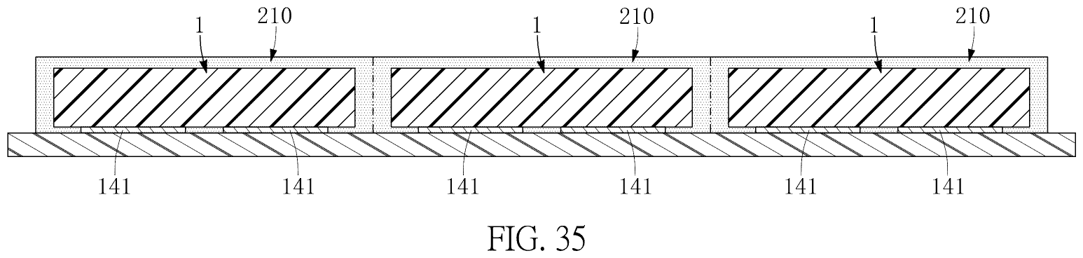

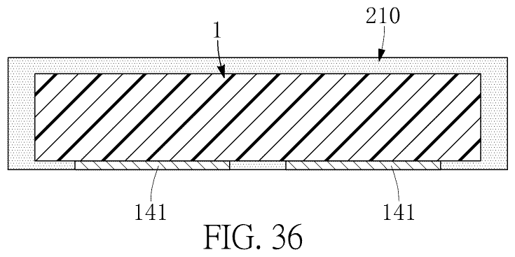

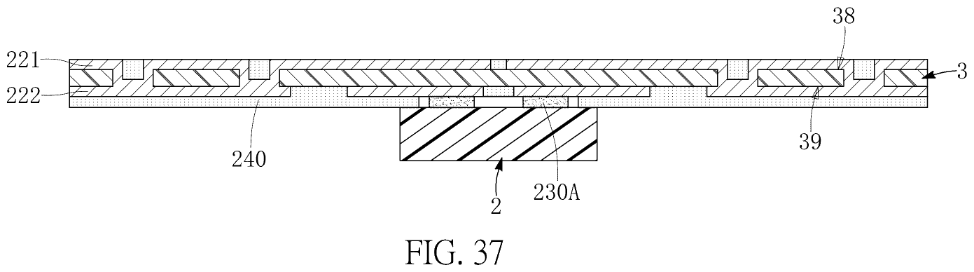

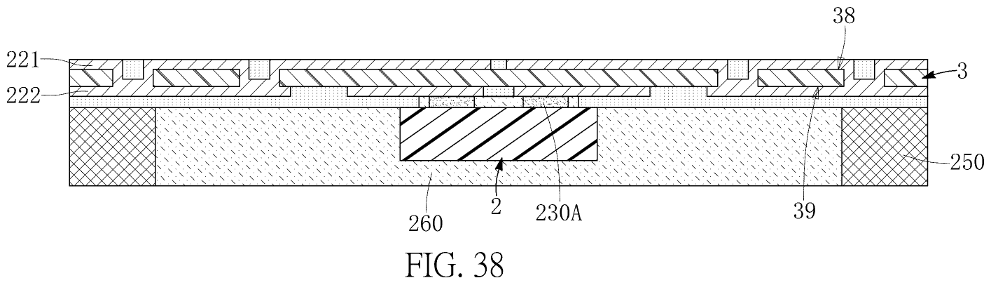

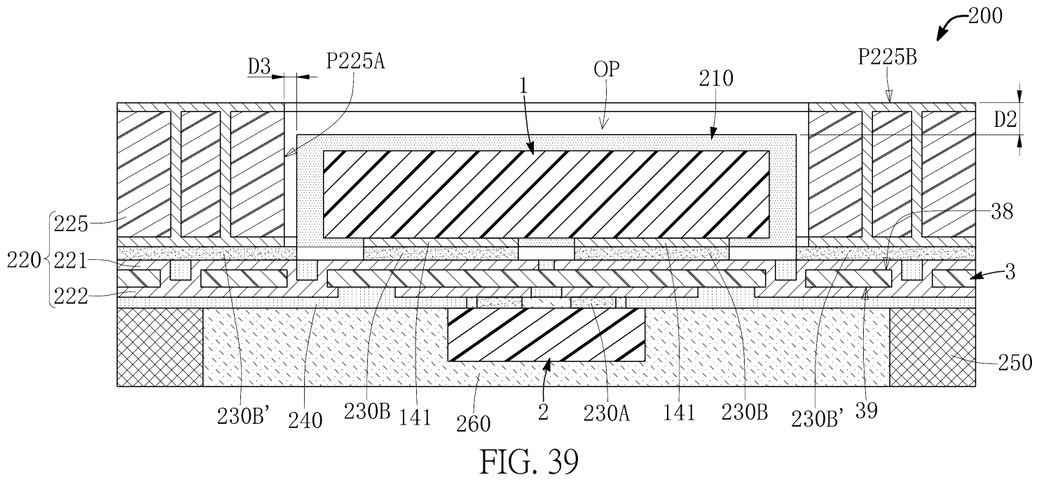

As shown in FIG. 3 to FIG. 5, the IC flip-chip 1 includes a chip body 11, a plurality of metal pads 12 electrically coupled to the chip body 11, a redistribution layer (RDL) 13 connected to the metal pads 12, a metal layer 14 connected to the redistribution layer 13, and a solder mask layer 15 covering the metal layer 14.

The solder mask layer 15 has a plurality of openings, and flip-chip pads 141 are defined by the metal layer 14 to be exposed from the solder mask layer 15 through the openings. The IC flip-chip 1 is bonded to the substrate 3 through the flip-chip pads 141.

The function of the chip body 11 (such as driving) corresponds to the LED flip-chips 2. The metal pads 12 are disposed on a surface 111 of the chip body 11 (e.g., a bottom surface of the chip body 11 in FIG. 3). The redistribution layer 13 is formed on the surface 111 of the chip body 11, and the metal pads 12 are embedded in the redistribution layer 13. The flip-chip pads 141 are disposed on the redistribution layer 13, and are electrically coupled to the metal pads 12 through the redistribution layer 13.

For instance, each of the metal pads 12 can be an aluminum pad that is suitable for wire bonding. That is, each of the metal pads 12 can be a wire bonding pad. Each of the metal pads 12 can further include an alloy layer. For instance, the alloy layer can be made of gold or nickel gold. The alloy layer can further be disposed on the aluminum pad.

Specifically speaking, through the redistribution layer 13, the metal pads 12 that are only suitable for a wire bonding process can extend their layout to form the flip-chips 141 that are suitable for a flip-chip process. For the sake of brevity, the redistribution layer 13 in the present embodiment is described with the following structure. However, the specific structure of the redistribution layer 13 can be adjusted and changed according to design requirements, and is not limited thereto.

The redistribution layer 13 has a multi-layer structure, and at least includes a first polymer layer 131, a wire extension layer 132, and a second polymer layer 133. The first polymer layer 131 is formed on the surface 111 of the chip body 11 and is arranged at a periphery of the metal pads 12. In the present embodiment, the first polymer layer 131 is coplanar with the metal pads 12 and is distributed on the entire surface 111.

The second polymer layer 133 is disposed on the first polymer layer 131, and the wire extension layer 132 is disposed on the first polymer layer 131 and the metal pads 12. The wire extension layer 132 is electrically coupled to the metal pads 12. The second polymer layer 133 is arranged around the wire extension layer 132, and the wire extension layer 132 is coplanar with the second polymer layer 133. The metal layer 14 is disposed on the wire extension layer 132 and protrudes out of a surface of the wire extension layer 132 and a surface of the second polymer layer 133.

Furthermore, the wire extension layer 132 can use materials that can be fixedly connected to the metal pads 12 (e.g., solder paste), and the metal layer 14 can use metal or alloy materials that can be wet and fixedly connected to the wire extension layer 132. Accordingly, the flip-chip pads 141 can use materials suitable for the flip-chip process. The metal layer 14 can be made of a wetting metal material or a wetting alloy material, such as gold or nickel gold.

The solder mask layer 15 is disposed on the metal layer 14, and the flip-chip pads 141 are exposed from the solder mask layer 15 through the openings. That is, a part of the metal layer 14 is embedded in the solder mask layer 15. More specifically, through the redistribution layer 13, the IC flip-chip 1 can enable the flip-chip pads 141 to be adjusted towards a plurality of faces suitable for the flip-chip process.

For instance, in the present embodiment, the material of any one of the flip-chip pads 141 (e.g., gold or nickel gold) is different from the material of any one of the metal pads 12 (e.g., aluminum). Each of the flip-chip pads 141 have a same area, and the area of any one of the flip-chip pads 141 is larger than an area of the metal pad 12 that is electrically coupled thereto. Accordingly, any one of the flip-chip pads 141 can have a stable connection in the flip-chip process.

Furthermore, through the redistribution layer 13, the IC flip-chip 1 can further enable the flip-chip pads 141 to be evenly distributed upon and corresponding to the surface 111. That is, the flip-chip pads 141 and the metal pads 12 each have a layout distribution, and the layout distribution of the flip-chip pads 141 is more even than the layout distribution of the metal pads 12, so as to facilitate application in the flip-chip process.

For the sake of brevity, edges of the metal pads 12 define a layout boundary B in the present embodiment, and the metal pads 12 are arranged within the layout boundary B. It should be noted that the layout boundary B is shown in a square shape in the present embodiment. However, the present disclosure is not limited thereto.

Furthermore, the flip-chip pads 141 are arranged within the layout boundary B, and at least one of the flip-chip pads 141 is spaced apart from the layout boundary B. In the present embodiment, edges of part of the flip-chip pads 141 (e.g., the two flip-chip pads 141 respectively arranged at locations near bottom left and top right of FIG. 5) are partially located on the layout boundary B, and a remaining part of the flip-chip pads 141 is spaced apart from the layout boundary B. Accordingly, through the redistribution layer 13, the IC flip-chip 1 can enable at least one of the flip-chip pads 141 to move toward an inner side of the layout boundary B, so that the flip-chip pads 141 are evenly distributed upon and corresponding to the surface 111.

Furthermore, to aid description of an even distribution of the flip-chip-pads 141 upon and corresponding to the surface 111, the layout boundary B further defines a nine-square grid area J. The nine-square grid area J has nine spaces that are substantially of the same size.

The number of spaces of the nine-square grid area J on which the metal pads 12 are located is lower than the number of the flip-chip pads 141. That is, at least one of the spaces of the nine-square grid area J corresponds to at least two of the metal pads 12, so that the distribution of the flip-chip pads 141 is dense.

Furthermore, a projection area is formed by an orthographic projection of the flip-chip pads 141 on the surface 111 of the chip body 1. The projection area is located on the nine-square grid area J, and the number of spaces of the nine-square grid area J on which the projection area is located is equal to the number of the metal pads 141. That is, any one of the spaces of the nine-square grid area J corresponds to at most one of the flip-chip pads 141. Accordingly, the flip-chip pads 141 are arranged to be evenly distributed, so that the flip-chip pads 141 can achieve an even wetting and are not easy to rotate in the flip-chip process, thereby facilitating a stable connection.

In other words, the projection area is formed by the orthographic projection of the flip-chip pads 141 on the surface 111 of the chip body 11, and the number of spaces of the nine-square grid area J on which the projection area is located (e.g., seven in the present embodiment) is greater than the number of spaces of the nine-square grid area J on which the metal pads 12 are located (e.g., five in the present embodiment).

Furthermore, the projection area formed by the orthographic projection of the flip-chip pads 141 on the surface 111 of the chip body 11 does not cover any one of the metal pads 12. Accordingly, any one of the flip-chips 141 and the corresponding metal pads 12 will not interfere with each other and affect the yield rate caused by the formation of the redistribution layer 13.

As shown in FIG. 2, FIG. 6, and FIG. 7, the substrate 3 carries the IC flip-chip 1 and the LED flip-chips 2, and the LED flip-chips 2 are spaced apart from the IC flip-chip 1. Furthermore, the LED flip-chips 2 have a plurality of electrodes 21, and the substrate 3 is electrically coupled to the flip-chip pads 141 of the IC flip-chip 1 and the electrodes 21 of the LED flip-chips 2.

Furthermore, in the flip-chip process, in order to enable the substrate 3 to be accurately connected to the flip-chip pads 141 of the IC flip-chip 1 and the electrodes 21 of the LED flip-chips 2, the substrate 3 is described in the present embodiment with the following structure. However, the specific structure of the substrate 3 can be adjusted and changed according to design requirements, and is not limited thereto.

The substrate 3 includes a first insulation layer 31, a first metal layer 32, a second insulation layer 33, a second metal layer 34, and a third metal layer 35. The first metal layer 32 and the second insulation layer 33 are arranged on two opposite sides of the first insulation layer 31, respectively. The second metal layer 34 and the third metal layer 35 are formed on the second insulation layer 33.

In the present embodiment, the first insulation layer 31 is in a step-shape, and the first insulation layer 31 has a lower step portion 311 and two upper step portions 312. The two upper step portions 312 are formed on the lower step portion 311 and are spaced apart from each other. The first metal layer 32 is formed on the two upper step portions 312 of the first insulation layer 31.

In the present embodiment, the first metal layer 32 includes an integrated circuit (IC) chip bonding region 321 and a light-emitting diode (LED) chip bonding region 322 that are respectively arranged on the two upper step portions 312.

The second insulation layer 33 is connected to the lower step portion 311 of the first insulation layer 31, and the second metal layer 34 is embedded in the first insulation layer 31 and the second insulation layer 33. The third metal layer 35 is arranged on a side of the second insulation layer 33 away from the first insulation layer 31.

The second metal layer 34 includes a plurality of extension wires 341 spanning the two upper step portions 312 and a plurality of conductive posts 342 connected to the extension wires 341. Through the conductive posts 342, the second metal layer 34 is correspondingly connected to the LED chip bonding region 322, the IC chip bonding region 321, and the third metal layer 35. Accordingly, the second metal layer 34 and the third metal layer 35 can be electrically coupled to each other, and the LED chip bonding region 322 can be electrically coupled to the IC chip bonding region 321 through the second metal layer 34.

Specifically speaking, in the present embodiment, the substrate 3 can further include an upper solder mask layer 36 and a lower solder mask layer 37. The upper solder mask layer 36 and the lower solder mask layer 37 are arranged on two opposite sides of the substrate 3, respectively. The upper solder mask layer 36 is formed on the first insulation layer 31. More specifically, the upper solder mask layer 36 is formed on the two upper step portions 312 of the first insulation layer 31. A plurality of perforations 361 are formed on the upper solder mask layer 36, so as to expose the IC chip bonding region 321 and the LED chip bonding region 322.

In the present embodiment, the upper solder mask layer 36 has a light-emitting diode (LED) chip solder mask area 363 and an integrated circuit (IC) chip solder mask area 362. The LED chip solder mask area 363 and the IC chip solder mask area 362 are spaced apart from each other, and the perforations 361 are formed on each of the LED chip solder mask area 363 and the IC chip solder mask area 362. More specifically, the LED chip solder mask area 363 and the IC chip solder mask area 362 are disposed on the two upper step portions 312. Furthermore, the lower solder mask layer 37 is disposed on the side of the second insulation layer 33 and is arranged adjacent to the third metal layer 35.

The surrounding wall 4 is disposed on the substrate 3 to define a first accommodating space 41 and a second accommodating space 42. The first accommodating space 41 corresponds in position to the IC chip solder mask area 362, and the second accommodating space 42 corresponds in position to the LED chip solder mask area 363. The IC flip-chip 1 is arranged in the first accommodating space 41, and the LED flip-chips 2 are arranged in the second accommodating space 42.

The light-permeable package body 5 is disposed on the substrate 3 and filled in the first accommodating space 41 and the second accommodating space 42, so that the IC flip-chip 1 and the LED flip-chips 2 are embedded therein. However, the present disclosure is not limited thereto. For instance, in embodiments not shown in the present disclosure, the light-permeable package body 5 can be filled only in the second accommodating space 42, so that the LED flip-chips 2 are embedded therein. Accordingly, in the present disclosure, the light-permeable package body 5 is filled at least in the second accommodating space 42.

Specifically speaking, in the present embodiment, the light-permeable package body 5 has a light emergent surface 51 that is parallel to the substrate 3 and faces toward a side that is away from the substrate 3. In the present embodiment, the light emergent surface 51 is coplanar with a top surface of the surrounding wall 4, but is not limited thereto.

It should be noted that the substrate 3 can also be understood as a multi-layer board structure. Specifically, the substrate 3 includes a first layer board, a second layer board disposed on a side of the first layer board, a third layer board disposed on a side of the second layer board away from the first layer board, and a fourth layer board that is disposed on a side of the third layer board away from the first layer board.

The first layer board carries the IC flip-chip 1 and the at least one LED flip-chip 2. The second layer board includes an upper insulating layer (e.g., the upper solder mask layer 36), a plurality of first conductive pads and a plurality of first conductive pillars (e.g., the first metal layer 32). The first conductive pads are disposed on the upper insulating layer, and the first conductive pads are electrically coupled to the flip-chip pads through the conductive pillars.

Moreover, the third layer board includes a lower insulating layer (e.g., the second insulation layer), a plurality of second conductive pads and a plurality of second conductive pillars (e.g., the second metal layer). The second conductive pads are disposed on the lower insulating layer, and the second conductive pads are electrically coupled to the first conductive pads through the second conductive pillars. The fourth layer board includes a plurality of outer pads (e.g., the third metal layer 35), and the outer pads are electrically coupled to the second conductive pads.

### Second Embodiment

Referring to FIG. 8 and FIG. 9, a second embodiment of the present disclosure is shown. Since the second embodiment is similar to the first embodiment above, the similarities of the two embodiments will not be reiterated. The differences between the second embodiment and the first embodiment above are briefly described as follows.

In the present embodiment, the light emergent surface 51 is perpendicular to the substrate 3 and faces toward a side that is away from the IC flip-chip 1. The light emergent surface 51 is not located on a top surface of the light-permeable package body 5. That is, the light emergent surface 51 is located on a side of the light-emitting device 100 and is coplanar with a side edge surface 44 of the surrounding wall 4. Furthermore, the first accommodating space 41 is a closed space wrapped in the surrounding wall 4. That is, the IC flip-chip 1 in the first accommodating space 41 and a corresponding part of the light-permeable package body 5 are embedded in the surrounding wall 4.

### Third Embodiment

Referring to FIG. 10 and FIG. 11, a third embodiment of the present disclosure is shown. Since the third embodiment is similar to the first embodiment above, the similarities of the two embodiments will not be reiterated. The differences between the third embodiment compared with the first embodiment above are briefly described as follows.

In the present embodiment, the IC flip-chip 1 is covered and embedded in the surrounding wall 4. That is, a space occupied by the IC flip-chip 1 in the surrounding wall 4 is the first accommodating space 41. The surrounding wall 4 further defines a third accommodating space 43, and the first accommodating space 41 is arranged between the second accommodating space 42 and the third accommodating space 43.

The light-emitting device 100 further includes a light sensor 6 arranged in the third accommodating space 43. The light-permeable package body 5 is filled in the second accommodating space 42 and the third accommodating space 43, so that the LED flip-chips 2 and the light sensor 6 are embedded therein. It should be noted that the LED flip-chips 2 can include two green LED chips and an infrared light chip, but are not limited thereto.

More specifically, in the present embodiment, the light-permeable package body 5 includes a light emergent surface 51 that corresponds in position to the LED flip-chips 2 and a light incident surface 52 that corresponds in position to the light sensor 6. The light emergent surface 51 and the light incident surface 52 are parallel to the substrate 3 and face toward a side that is away from the substrate 3.

In the present embodiment, the light emergent surface 51 and the light incident surface 52 are coplanar with the top surface of the surrounding wall 4.

However, the present disclosure is not limited thereto. In the present embodiment, the light-emitting device 100 simultaneously integrates the IC flip-chip 1 (e.g., an analog front-end chip), light sources, and the light sensor 6. Accordingly, the light-emitting device 100 is more suitable for thin and light wearable devices, and is configured to provide a light-emitting diode package structure that is smallest in size and thinnest in thickness.

### Fourth Embodiment

Referring to FIG. 12 and FIG. 13, a fourth embodiment of the present disclosure is shown. Since the fourth embodiment is similar to the first embodiment above, the similarities of the two embodiments will not be reiterated. The differences between the fourth embodiment compared with the first embodiment above are briefly described as follows.

In the present embodiment, a light-emitting assembly 10 is provided, and a difference between the light-emitting assembly 10 and the light-emitting device 100 of the first embodiment is that the light-emitting assembly 10 does not include the substrate 3. The light-emitting assembly 10 includes an integrated circuit (IC) flip-chip 1, a plurality of light-emitting diode (LED) flip-chips 2 spaced apart from the IC flip-chip 1, and a light-permeable package body 5.

In the present embodiment, since the IC flip-chip 1 and the LED flip-chips 2 are similar to those of the first embodiment above, details thereof will not be reiterated herein. The LED flip-chips 2 can be one of red LED chips, blue LED chips and green LED chips, or a combination thereof, but are not limited thereto.

In the present embodiment, the light-emitting assembly 10 does not include the substrate 3 of the first embodiment, and the light-permeable package body 5 is an integrally formed one-piece structure and covers the IC flip-chip 1 and the LED flip-chips 2. The flip-chip pads 141 of the IC flip-chip 1 and the electrodes 21 of the LED flip-chips 2 are exposed outside of the light-permeable package body 5 and are configured to be mounted on a predetermined object (such as a circuit board or a substrate).

### Fifth Embodiment

Referring to FIG. 14 to FIG. 17, a fifth embodiment of the present disclosure is shown. Since the fifth embodiment is similar to the first embodiment above, the similarities of the two embodiments will not be reiterated. The differences between the fifth embodiment compared with the first embodiment above are briefly described as follows.

A plurality of projection areas are defined by orthogonally projecting the flip-chip pads (i.e., 141A to 141G in FIG. 14 or 141A to 141H in FIG. 16) of the IC flip-chip 1 onto the surface 111 of the chip body 11, and each of positions of the projection areas is not within a central region CA of the layout boundary (as shown in FIG. 15 and FIG. 17). It can be understood as any one of the flip-chip pads is not located in the central region CA.

Specifically, the edges of the metal pads 12 define a layout boundary B located on the surface 111 of the chip body 11, and the layout boundary B in the present embodiment generally overlaps an outline of the chip body 11. The layout boundary B also defines a nine-square grid area, and the central region CA can be located in a central grid in the nine-square grid area.

For example, as shown in FIG. 15, the flip-chip pads define a first flip-chip pad 141A, a second flip-chip pad 141B, a third flip-chip pad 141C, a fourth flip-chip pad 141D, a fifth flip-chip pad 141E, a sixth flip-chip pad 141F, and a seventh flip-chip pad 141G. The nine-square grid area has a first grid J1, a second grid J2, . . . , and a ninth grid J9 from left to right and top to bottom. A location of the first flip-chip pad 141A is generally located in the first grid J1, a location of the second flip-chip pad 141B is generally located in the second grid J2, a location of the third flip-chip pad 141C is generally located between the third grid J3 and the sixth grid J6, a location of the fourth flip-chip pad 141D is generally located in the fourth grid J4, a location of the fifth flip-chip pad 141E is generally located between the sixth grid J6 and the ninth grid J9, a location of the sixth flip-chip pad 141F is generally located in the seventh grid J7, and a location of the seventh flip-chip pad 141G is generally located in the eighth grid J8. Any one of the flip-chip pads is not located in the fifth grid J5. Accordingly, compared to the first embodiment, the light-emitting device 100 in the present embodiment can prevent a pin of the chip-pick-up machine from damaging the pads during the die bonding process, so as to ensure product reliability.

It is worth noting that the area of the central region CA is preferably less than or equal to any one of the flip-chip pads. In other words, any one of the flip-chip pads does not locate in a central range corresponding in position to the chip body 11, so as to avoid a possibility of the pin of the chip-pick-up machine damaging the flip-chip pad. At the same time, the flip-chip pads are evenly arranged around a lower surface of the chip body 11 to improve product reliability.

Specifically, as shown in FIG. 17, the flip-chip pads define a first flip-chip pad 141A, a second flip-chip pad 141B, a third flip-chip pad 141C, a fourth flip-chip pad 141D, a fifth flip-chip pad 141E, a sixth flip-chip pad 141F, a seventh flip-chip pad 141G, and an eighth flip-chip pad 141H. A location of the first flip-chip pad 141A is generally located in the first grid J1, a location of the second flip-chip pad 141B is generally located between the second grid J2 and the fifth grid J5, a location of the third flip-chip pad 141C is generally located in the third grid J3, a location of the fourth flip-chip pad 141D is generally located in the fourth grid J4, a location of the fifth flip-chip pad 141E is generally located in the sixth grid J6, a location of the sixth flip-chip pad 141F is generally located in the seventh grid J7, and a location of the seventh flip-chip pad 141G is generally located between the eighth grid J8 and the fifth grid J5. Although a portion of the second flip-chip pad 141B and a portion of the seventh flip-chip pad 141G are located in the fifth grid J5, positions of the second flip-chip pad 141B and the seventh flip-chip pad 141G are not located in the central region CA in the fifth grid J5 (i.e., a circular region).

As shown in FIG. 15 and FIG. 17, each of side edges of the layout boundary B corresponds in position to at least two of the flip-chip pads, such that the positions of the flip-chip pads on the IC flip-chip 1 are more evenly distributed. Furthermore, considering the nine-square grid area, the first column, the third column, the first row, and the third row each include at least two of the projection areas (i.e., the flip-chip pads).

Accordingly, when the IC flip-chip 1 is in the soldering process, the at least two of the flip-chip pads corresponding in position to the side edges of the layout boundary B can ensure uniform stress on the IC flip-chip 1 generated by the solder, so as to increase a bonding reliability between the IC flip-chip 1 and the substrate 3.

Preferably, to avoid the occurrence of warping or rotation of the IC flip-chip 1, at least a part of the projection area can be symmetrically arranged along at least one axis SA passing through a center point of the layout boundary B.

In one embodiment, as shown in FIG. 15, the quantity of the at least one axis SA is one. When viewed with the axis SA passing through the fourth grid J4, the fifth grid J5, the sixth grid J6, and a center point of the nine-square grid area, the first flip-chip pad 141A, the fourth flip-chip pad 141D, and the sixth flip-chip pad 141F form a first symmetric group SG1, the second flip-chip pad 141B and the seventh flip-chip pad 141G form a second symmetric group SG2, and the third flip-chip pad 141C and the fifth flip-chip pad 141E form a third symmetric group SG3.

In another embodiment, as shown in FIG. 17, when viewed with the axis SA passing through the fourth grid J4, the fifth grid J5, the sixth grid J6, and a center point of the nine-square grid area, the first flip-chip pad 141A, the fourth flip-chip pad 141D, and the sixth flip-chip pad 141F form a first symmetric group SG1, the second flip-chip pad 141B and the seventh flip-chip pad 141G form a second symmetric group SG2, and the third flip-chip pad 141C, the fifth flip-chip pad 141E, and the eighth flip-chip pad 141H form a third symmetric group SG3.

In principle, the IC flip-chip 1 should have at least one of the first symmetric group SG1, the second symmetric group SG2, and the third symmetric group SG3.

Naturally, the quantity of the at least one axis SA can be multiple. For example, in another embodiment of the present disclosure (not shown), the quantity of the flip-chip pads is eight in total, and positions of the flip-chip pads are respectively located at centers of the first grid J1, the second grid J2, the third grid J3, the fourth grid J4, the sixth grid J6, the seventh grid J7, the eighth grid J8, and the ninth grid J9. Based on the example, the quantity of the at least one axis SA is more than four, and the IC flip-chip 1 includes more than six symmetric groups.

In addition, to ensure optimal performance, such as uniformity, of the red, blue, and green light emitted by the light-emitting device 100 during color mixing, the LED flip-chips can have a triangular arrangement, as shown in FIG. 14. Specifically, the LED flip-chips in the present embodiment have a red light diode chip 2R, a green light diode chip 2G, and a blue light diode chip 2B, and a long axis of the red light diode chip 2R, a long axis of the green light diode chip 2G, and a long axis of the blue light diode chip 2B are parallel to each other. A long axis extension line of the red light diode chip 2R and a long axis extension line of the green light diode chip 2G can overlap, and the long axis of the blue light diode chip 2B is located on a common side of the red light diode chip 2R and the green light diode chip 2G, but the present disclosure is not limited thereto.

For example, in another embodiment, when the light-emitting device 100 can emit red light, blue light, green light, and white light for light mixing, the LED flip-chips may be arranged in a matrix (as shown in FIG. 16). Specifically, the LED flip-chips in the present embodiment include a red light diode chip 2R, a green light diode chip 2G, a blue light diode chip 2B, and a white light diode chip 2W. A short axis extension line of the red light diode chip 2R, a short axis extension line of the green light diode chip 2G, and a short axis extension line of the blue light diode chip 2B can overlap with each other, and the white light diode chip 2W is located on a common side of the red light diode chip 2R, the green light diode chip 2G and the blue light diode chip 2B. For example, as depicted in FIG. 16, the white light diode chip 2W is positioned to the right of the red light diode chip 2R, the green light diode chip 2G, and the blue light diode chip 2B.

### Sixth Embodiment

Referring to FIG. 18 to FIG. 26, a sixth embodiment of the present disclosure is shown. Since the sixth embodiment is similar to the fifth embodiment above, the similarities of the two embodiments will not be reiterated. The differences between the sixth embodiment compared with the fifth embodiment above are briefly described as follows.

As shown in FIG. 18, the substrate 3 of the light-emitting device 200 in the present embodiment has a first plate surface 38 and a second plate surface 39 that are opposite to each other, and the quantity of the at least one LED flip-chip 2 is one. Specifically, the IC flip-chip 1 is disposed on the first plate surface 38, and the LED flip-chip 2 is disposed on the second plate surface 39. In other words, the IC flip-chip 1 and the LED flip-chip 2 are arranged vertically on the substrate 3.

It should be noted that achieving miniaturization within the same volume, the light-emitting device 200 of the present embodiment, with a vertical arrangement, offers more emitting area for the LED flip-chip 2 compared to the light-emitting device 100 of the first embodiment, which adopts a planar configuration (as shown in FIG. 7). In other words, under the condition of the same luminous flux, the light-emitting device 200 of the present embodiment can also save more volume compared to the light-emitting device 100 of the first embodiment.

In addition, the light-emitting device 200 in the present embodiment also includes a resin layer 210, a connecting circuit 220, a plurality of solders 230, a solder resist coating 240, and a reflective wall 250.

The resin layer 210 is disposed on the first plate surface 38, and the IC flip-chip 1 is covered by the resin layer 210. The connecting circuit 220 is disposed on the first plate surface 38, the second plate surface 39, and the resin layer 210, and the LED flip-chip 2 can be electrically coupled to the IC flip-chip 1 through the connecting circuit 220.

Specifically, the connecting circuit 220 includes a first circuit layer 221, a second circuit layer 222, a plurality of conductive pillars 223 and an outer circuit layer 224. The first circuit layer 221 is disposed on the first plate surface 38, and the first circuit layer 221 is covered by the resin layer 210.

In addition, the first circuit layer 221 can be electrically coupled to the flip-chip pads 141 through the solders 230. That is to say, each of the solders 230 is disposed between the first circuit layer 221 and the flip-chip pads 141. The IC flip-chip 1 can be fixed on the first circuit layer 221 through the solders 230 and be electrically coupled to the first circuit layer 221.

The second circuit layer 222 is disposed on the second plate surface 39, and the second circuit layer 222 is electrically coupled to the LED flip-chip 2 and the first circuit layer 221. In practice, the second circuit layer 222 can be electrically coupled to the first circuit layer 221 through a plurality of via holes on the substrate 3, such that the second circuit layer 222 can be electrically coupled to the LED flip-chip 2 through the flip-chip pads 141 that are electrically coupled to the first circuit layer 221.

In addition, the outer circuit layer 224 is disposed on an outer surface P210 of the resin layer 210 away from the substrate 3, and the outer circuit layer 224 can be used to connect an external circuit or component. The outer circuit layer 224 is electrically coupled to the first circuit layer 221 through the conductive pillars 223 embedded in the resin layer 210. That is to say, one of two ends of each of the conductive pillars 223 is electrically coupled to the first circuit layer 221, and another one of the two ends of each of the conductive pillars 223 is electrically coupled to the outer circuit layer 224.

It is worth noting that the conductive pillars 223 may preferably be a hollow structure, and each of the conductive pillars 223 has a filling space SP that is configured to be filled by a part of the resin layer 210. Specifically, the resin layer 210 includes a covering portion 211 and a filling portion 212. The covering portion 211 is disposed on the first plate surface 38 and the IC flip-chip 1 is covered by the covering portion 211, such that the covering portion 211 has the outer surface P210 provided with the outer circuit layer 224. A predetermined distance D1 is between the outer surface P210 of the covering portion 211 and the chip body 11, and the predetermined distance D1 is preferably more than 30 micrometers, so that the covering portion 211 can adequately protect the chip body 11 while maintaining miniaturization.

In addition, the covering portion 211 has a plurality of setting holes 2111 that are respectively provided with the conductive pillars 223. In practice, each of the conductive pillars 223 may be formed by coating an inner edge of each of the setting holes 2111 with conductive metal, and each of the conductive pillars 223 generates the filling space SP in the setting hole 2111. The filling portion 212 is filled into the filling spaces SP of the conductive pillars 223.

It should be noted that, in practice, a design of “each of the conductive pillars 223 having the filling space SP and filled with the filling portion 212” can be adjusted according to practical requirements. For example, in another embodiment of the present disclosure (not shown), each of the conductive pillars 223 may also be solid (i.e., the conductive pillars 223 do not have the filling space SP), so that the resin layer 210 does not have the filling portion 212 filling the filling space SP.

Referring to FIG. 18, the solder resist coating 240 is disposed on the outer surface P210 and the second plate surface 39, and the outer circuit layer 224 and the second circuit layer 222 are surrounded by the solder resist coating 240. That is to say, the solder resist coating 240 may be coated on a non-conductive area of the outer surface P210 and a non-conductive area of the second plate surface 39, so that the solder resist coating 240 can improve the circuit reliability of the light-emitting device 200.

As shown in FIG. 18, the reflective wall 250 is disposed on the second plate surface 39, and the LED flip-chip 2 is surrounded by the reflective wall 250. In addition, the light-emitting device 200 may also include a light-transmitting package 260 that is filled in the reflective wall 250 to cover the LED flip-chip 2.

Naturally, in practice, the reflective wall 250 and the light-transmitting package 260 can also be omitted according to practical requirements. In other words, the light-emitting device 200 of the present disclosure is not limited to having the reflective wall 250 and the light-transmitting package 260.

To facilitate a better understanding of the light-emitting device 200 of the present embodiment, below is an illustrative example of one manufacturing process of the light-emitting device 200, but the present disclosure is not limited thereto. As shown in FIG. 19, the manufacturing method of the light-emitting device 200 includes steps S101 to S117.

The step S101 is implemented by fixing an IC flip-chip 1 on a first plate surface 38 located on a substrate 3 through a plurality of solders 230 (e.g., solder balls), so that the IC flip-chip 1 is electrically coupled to a first circuit layer 221 on the substrate 3 (as shown in FIG. 20).

The step S103 is implemented by covering a resin material on the first plate surface 38 through a vacuum heat press (not shown), so that the resin material generates a covering portion 211 (as shown in FIG. 21).

The step S105 is implemented by opening a plurality of setting holes 2111 on the covering portion 211 through a laser device (not shown), and the setting holes 2111 corresponding in position to the first circuit layer 221 (as shown in FIG. 22).

The step S107 is implemented by plating a conductive metal on a surface of the covering portion 211 and an inner edge of each of the setting holes 2111 (as shown in FIG. 23).

The step S109 is implemented by processing the conductive metal and a metal surface located on a second plate surface 39 of the substrate 3 by etching, so that the conductive metal located on the surface of the covering portion 211 is formed into an outer circuit layer 224, the conductive metal located at the inner edge of each of the setting holes 2111 is formed into a conductive pillar 223 that is a hollow structure, and the metal surface located on the second plate surface 39 is formed into a second circuit layer 222 (as shown in FIG. 24).

The step S111 is implemented by filling a resin material in each of the conductive pillars 223 to form a filling portion 212 and plating a conductive metal to cover the resin material (i.e., a part of the outer circuit layer 224, as shown in FIG. 25). The manufacturing method of the light-emitting device 200 can omit the step S111 according to practical requirements. For example, when each of the conductive pillars 223 is a solid, the step S113 can be directly implemented after the step S109 is completed.

The step S113 is implemented by coating a solder resist material on the surface of the covering portion 211 and the second plate surface 39 to form a solder resist coating 240 (as shown in FIG. 25).

The step S115 is implemented by fixing the LED flip-chip 2 to the second plate surface 39 through a plurality of solders 230 (e.g., solder balls), so that the LED flip-chip 2 is electrically coupled to the second circuit layer 222 (as shown in FIG. 26).

The step S117 is implemented by setting a reflective wall 250 and a light-transmitting package 260 on the second plate surface 39, so that the LED flip-chip 2 is surrounded by the reflective wall 250 and is covered by the light-transmitting package 260 (as shown in FIG. 18). The manufacturing method of the light-emitting device 200 can omit the step S117 according to practical requirements. For example, when the light-emitting device 200 does not set the reflective wall 250 and the light-transmitting package 260 according to the practical requirements, the light-emitting device 200 can be obtained by completing the step S115.

### Seventh Embodiment

Referring to FIG. 27 to FIG. 39, a seventh embodiment of the present disclosure is shown. Since the seventh embodiment is similar to the sixth embodiment above, the similarities of the two embodiments will not be reiterated. The differences between the seventh embodiment compared with the sixth embodiment above are briefly described as follows.

As shown in FIG. 27, the covering portion 211 of the resin layer 210 is disposed on the first plate surface 38 and covers the IC flip-chip 1. In other words, the covering portion 211 in the present embodiment only covers the IC flip-chip 1 and partially covers the first circuit layer 221, and the covering portion 211 does not completely cover the first circuit layer 221.

In addition, the connecting circuit 220 in the present embodiment has a circuit covering plate 225, and the circuit covering plate 225 replaces the conductive pillars 223 and the outer circuit layer 224 of the sixth embodiment. Specifically, the circuit covering plate 225 is disposed on the first plate surface 38, and the circuit covering plate 225 can be electrically coupled to the first circuit layer 221. A height of the circuit covering plate 225 in the present embodiment is greater than a height of the reflective wall 250, but the present disclosure is not limited thereto.

Moreover, the circuit covering plate 225 has an opening OP, and the opening OP can accommodate the IC flip-chip 1 and the resin layer 210. In other words, the IC flip-chip 1 and the resin layer 210 are surrounded by the circuit covering plate 225.

A predetermined distance D2 is between an outer surface P225B of the circuit covering plate 225 away from the substrate 3 and the resin layer 210, and the predetermined distance D2 is preferably more than 30 micrometers, so that the circuit covering plate 225 can protect the IC flip-chip 1 in the opening OP.

In addition, in order to ensure that the IC flip-chip 1 has an ideal heat dissipation environment, the circuit covering plate 225 has a heat dissipation gap D3 between an inner side P225A of the opening OP and the resin layer 210 (i.e., the heat dissipation gap D3 is in spatial communication with the opening OP), and the heat dissipation gap D3 is preferably more than 50 micrometers.

It is worth noting that the circuit covering plate 225 and the IC flip-chip 1 in the present embodiment are electrically coupled to the first circuit layer 221 through a plurality of low-temperature solders (i.e., 230B, 230B′ in FIG. 27) of the light-emitting device 200. Specifically, the low-temperature solders are disposed between the first circuit layer 221 and the circuit covering plate 225, and between the first circuit layer 221 and the flip-chip pads 141, so that the circuit covering plate 225 and the IC flip-chip 1 can be fixed on the first circuit layer 221 through the low-temperature solders.

In order to cooperate with the low-temperature solders, the LED flip-chip is electrically coupled to the second circuit layer 222 through a plurality of high-temperature solders 230A of the light-emitting device 200. In other words, the high-temperature solders 230A are disposed between the second circuit layer 222 and the LED flip-chip 2, so that the LED flip-chip 2 is fixed on the second circuit layer 222 through the high-temperature solder 230A. Each of the high-temperature solders refers to a soldering material with a higher melting point compared to each of the low-temperature solders, and a melting point difference between the high-temperature solders 230A and the low-temperature solders is greater than or equal to 20° C. Accordingly, the light-emitting device 200 can be more easily manufactured by using the low-temperature solders and the high-temperature solders 230A.

To facilitate a better understanding of the light-emitting device 200 of the present embodiment (e.g., a manufacturing advantage generated by the low-temperature solders and the high-temperature solders 230A), below is an illustrative example of one manufacturing process of the light-emitting device 200, but the present disclosure is not limited thereto. As shown in FIG. 28, the manufacturing method of the light-emitting device 200 includes steps S201 to S209.

The step S201 is implemented by fixing the LED flip-chip 2 on a second plate surface 39 of a substrate 3 with double-sided circuits and a solder resist coating 240 through a plurality of high-temperature solders 230A (e.g., high-temperature solder balls), so that the LED flip-chip 2 is electrically coupled to a second circuit layer 222 on the second plate surface 39 (as shown in FIG. 29).

The step S203 is implemented by setting a reflective wall 250 and a light-transmitting package 260 on the second plate surface 39, so that the LED flip-chip 2 is surrounded by the reflective wall 250, and the LED flip-chip 2 is covered by the light-transmitting package 260 (as shown in FIG. 30). The manufacturing method of the light-emitting device 200 can omit the step S203 according to the practical requirements. For example, when the light-emitting device 200 does not set the reflective wall 250 and the light-transmitting package 260 according to the practical requirements, the step S205 can be directly implemented after the step S201 is completed.

The step S205 is implemented by fixing the IC flip-chip 1 on a first plate surface 38 located on the substrate 3 through a plurality of first low-temperature solder 230B (e.g., low-temperature solder balls), so that the IC flip-chip 1 is electrically coupled to a first circuit layer 221 on the substrate 3 (as shown in FIG. 31).

The step S207 is implemented by molding a resin material onto the IC flip-chip 1, so that the appearance of the IC flip-chip 1 forms a resin layer 210 (as shown in FIG. 32). The resin material can be molded onto the IC flip-chip 1 through a mold M, but the present disclosure is not limited thereto.

The step S209 is implemented by fixing a circuit covering plate 225 on the first plate surface 38 of the substrate 3 through a plurality of second low-temperature solder 230B′ (e.g., low-temperature solder balls) and the IC flip-chip 1 being surrounded by the circuit covering plate 225, so that the circuit covering plate 225 is electrically coupled to the first circuit layer 221 on the substrate (as shown in FIG. 27).

Accordingly, the LED flip-chip 2 is prevented from being separated from the second circuit layer 222 due to step S209 by utilizing the high-temperature solder 230A. The light-emitting device 200 can be manufactured through the above steps S201 to S209, but the manner in which the resin layer 210 encapsulates the IC flip-chip 1 may vary. As another example, as shown in FIG. 33, the method of manufacturing a light-emitting device includes steps S301 to S311.

The step S301 is implemented by obtaining an additional circuit board 300 equipped with a plurality of IC flip-chips 1 (as shown in FIG. 34).

The step S303 is implemented by coating a resin material on the additional circuit board 300, so that surface of each of the IC flip-chips 1 is formed with a resin layer 210 (as shown in FIG. 35).

The step S305 is implemented by cutting and removing the additional circuit board 300, so as to obtain one of the IC flip-chips 1 covered with the resin layer 210 (as shown in FIG. 36).

The step S307 is implemented by fixing the LED flip-chip 2 on a second plate surface 39 of a substrate 3 with double-sided circuits through a plurality of high-temperature solders 230A (e.g., high-temperature solder balls), so that the LED flip-chip 2 is electrically coupled to a second circuit layer 222 on the second plate surface 39 (as shown in FIG. 37).

The step S309 is implemented by setting a reflective wall 250 and a light-transmitting package 260 on the second plate surface 39, so that the LED flip-chip 2 is surrounded by the reflective wall 250, and the LED flip-chip 2 is covered by the light-transmitting package 260 (as shown in FIG. 38). The manufacturing method of the light-emitting device 200 can omit the step S309 according to the practical requirements. For example, when the light-emitting device 200 does not set the reflective wall 250 and the light-transmitting package 260 according to the practical requirements, the step S311 can be directly implemented after the step S307 is completed.

The step S311 is implemented by fixing the IC flip-chip 1 and a circuit covering plate 225 on a first plate surface 38 of the substrate 3 through a plurality of low-temperature solders 230, 230′ (e.g., low-temperature solder balls), so that the IC flip-chip 1 and the circuit covering plate 225 are electrically coupled to a first circuit layer 221 on the substrate 3 (as shown in FIG. 39).

Accordingly, the light-emitting device 200 can be manufactured through the steps S301 to S311.

### Beneficial Effects of the Embodiments

Therefore, in the integrated circuit flip-chip and the light-emitting device provided by the present disclosure, by virtue of “a distribution of the flip-chip pads being more even than a distribution of the metal pads,” the integrated circuit flip-chip and the light-emitting device can provide ideal product reliability while being miniaturized.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A integrated circuit (IC) flip-chip, comprising:
a chip body having a surface;
a plurality of metal pads disposed on the surface of the chip body;
a plurality of flip-chip pads disposed on the metal pads, wherein the flip-chip pads are electrically coupled to the metal pads through a redistribution layer therebetween;
wherein a distribution of the flip-chip pads is more even than a distribution of the metal pads.

2. The IC flip-chip according to claim 1, wherein any one of the metal pads is not covered by a projection area formed by an orthographic projection of the flip-chip pads on the surface of the chip body.

3. The IC flip-chip according to claim 1, wherein edges of the metal pads define a layout boundary, and the flip-chip pads are arranged within the layout boundary.

4. The IC flip-chip according to claim 3, wherein the layout boundary defines a nine-square grid area, a number of spaces of the nine-square grid area on which the flip-chip pads are located is greater than a number of spaces of the nine-square grid area on which the metal pads are located.

5. The IC flip-chip according to claim 3, wherein edges of part of the flip-chip pads are partially located on the layout boundary, and a remaining part of the flip-chip pads is spaced apart from the layout boundary.

6. The IC flip-chip according to claim 1, wherein the redistribution layer includes:
a first polymer layer formed on the surface of the chip body and arranged around the metal pads;
a wire extension layer disposed on the first polymer layer and the metal pads, wherein the wire extension layer is electrically coupled to the metal pads; and
a second polymer layer arranged around the wire extension layer, wherein a portion of the wire extension layer is located on an outer side of the second polymer layer.

7. The IC flip-chip according to claim 6, wherein the redistribution layer further includes a solder mask layer that is disposed on the second polymer layer and the wire extension layer, and the flip-chip pads are exposed from the solder mask layer.

8. The IC flip-chip according to claim 3, wherein any one of the flip-chip pads is not located in a central region of the layout boundary.

9. The IC flip-chip according to claim 3, wherein each of side edges of the layout boundary corresponds in position to at least two of the flip-chip pads.

10. The IC flip-chip according to claim 3, wherein the flip-chip pads are symmetrically arranged along at least one axis passing through a center point of the layout boundary.

11. The IC flip-chip according to claim 3, wherein at least one of the flip-chip pads is configured to move toward an inner side of the layout boundary.

12. The IC flip-chip according to claim 1, wherein a material of any one of the flip-chip pads is different from a material of any one of the metal pads.

13. The IC flip-chip according to claim 1, wherein each of the flip-chip pads has a same area.

14. The IC flip-chip according to claim 1, wherein an area of any one of the flip-chip pads is larger than an area of the metal pad that is electrically coupled thereto.

15. A light-emitting device, comprising:
a substrate;
the IC flip-chip as claimed in claim 1, wherein the IC flip-chip is disposed on the substrate; and
at least one light-emitting diode (LED) flip-chip spaced apart from the IC flip-chip, wherein the at least one LED flip-chip is electrically coupled to the IC flip-chip by the substrate.

16. The light-emitting device according to claim 15, wherein the substrate includes:
a first layer board, wherein the IC flip-chip and the at least one LED flip-chip are disposed on the first layer board;
a second layer board disposed on one side of the first layer board, wherein the second layer board includes an upper insulating layer, a plurality of first conductive pads, and a plurality of first conductive pillars, and wherein the first conductive pads are disposed on the upper insulating layer, and the first conductive pads are electrically coupled to the flip-chip pads through the first conductive pillars;
a third layer board disposed on a side of the second layer board away from the first layer board, wherein the third layer board includes a lower insulating layer, a plurality of second conductive pads, and a plurality of second conductive pillars, and wherein the second conductive pads are disposed on the lower insulating layer, and the second conductive pads are electrically coupled to the first conductive pads through the second conductive pillars; and
a fourth layer board disposed on a side of the third layer board away from the first layer board, wherein the fourth layer board includes a plurality of outer pads, and the outer pads are electrically coupled to the second conductive pads.

17. The light-emitting device according to claim 16, wherein a first predetermined separation distance is between any two adjacent ones of the first conductive pads and between any two adjacent ones of the second conductive pads, and a second predetermined separation distance is between one of the first conductive pads adjacent to an edge of the upper insulating layer and the edge of the upper insulating layer, and between one of the second conductive pads adjacent to an edge of the lower insulating layer and the edge of the lower insulating layer; wherein each of the first predetermined separation distance and the second predetermined separation distance is 60 microns.

18. The light-emitting device according to claim 16, wherein the at least one LED flip-chip includes a red light diode chip, a green light diode chip, and a blue light diode chip, wherein a long axis of the red light diode chip, a long axis of the green light diode chip, and a long axis of the blue light diode chip are parallel to each other, and the red light diode chip, the green light diode chip, and the blue light diode chip have a triangular arrangement.

19. The light-emitting device according to claim 16, wherein the at least one LED flip-chip includes a red light diode chip, a green light diode chip, a blue light diode chip, and a white light diode chip, wherein a short axis extension line of the red light diode chip, a short axis extension line of the green light diode chip, and a short axis extension line of the blue light diode chip overlap with each other, and the white light diode chip is arranged on a common side of the red light diode chip, the green light diode chip and the blue light diode chip.
